(19) United States
(12) Patent Application Publication
(10) Pub. No.: US 2026/0026171 A1
(43) Pub. Date: Jan. 22, 2026

(54) DISPLAY DEVICE, METHOD FOR MANUFACTURING THE SAME AND ELECTRONIC DEVICE

(71) Applicant: Samsung Display Co., Ltd., Yongin-si (KR)

(72) Inventors: Kyung Rock SON, Yongin-si (KR); Gwang Geun LEE, Yongin-si (KR); Jae Phil LEE, Yongin-si (KR); Won Ho JANG, Yongin-si (KR)

(21) Appl. No.: 19/228,599

(22) Filed: Jun. 4, 2025

(30) Foreign Application Priority Data
Jul. 19, 2024 (KR) 10-2024-0095485

(51) Int. Cl. H10H 29/80; H10H 29/01; H10H 29/49

(52) U.S. Cl. CPC H10H 29/8325; H10H 29/012; H10H 29/032; H10H 29/0364; H10H 29/49; H10H 29/8323

(57) ABSTRACT

A display device includes a substrate, a pixel electrode disposed on the substrate, an organic layer disposed on the pixel electrode, a light emitting element disposed on the organic layer, including a semiconductor stack, a first protective layer, a contact electrode, and a second protective layer, a connection electrode connecting the light emitting element and the pixel electrode, wherein the first protective layer is an insulating protective layer, the second protective layer is a conductive protective layer, wherein the connection electrode and the second protective layer are etchable with the same etchant.

### CROSS-REFERENCE TO RELATED APPLICATION

The present application claims priority to and the benefit of Korean Patent Application No. 10-2024-0095485, filed on Jul. 19, 2024, in the Korean Intellectual Property Office, the entire disclosure of which is incorporated herein by reference.

### BACKGROUND

### 1. Field

One or more aspects of embodiments of the present disclosure are directed toward to a display device, a method for manufacturing the display device and the electronic device including the display device.

### 2. Description of the Related Art

As the use of display devices become more widespread, the demand or desire for display devices in various suitable forms is increasing. The display device may be a flat panel display device such as a liquid crystal display, a field emission display, a light emitting display, and/or the like.

The light emitting display device may include an organic light emitting display device including an organic light emitting diode element as a light emitting element, and/or a micro light emitting display device including a micro light emitting diode element (hereinafter referred to as a micro light emitting diode element) as a light emitting element. Because the micro light emitting diode element is made of inorganic materials, it may present less deterioration issues and may have a longer lifespan compared to organic light emitting diode elements.

### SUMMARY

One or more aspects and features of embodiments of the present disclosure are directed toward a display device and a manufacturing method thereof that may increase the light emission rate of the light emitting element and reduce power consumption and facilitate the process.

However, the present disclosure is not limited to those embodiments set forth herein. The above and other embodiments of the present disclosure will become more apparent to one of ordinary skill in the art to which the present disclosure pertains by referencing the detailed description of the present disclosure.

According to one or more embodiments of the present disclosure, a display device includes a substrate, a pixel electrode arranged on the substrate, an organic layer arranged on the pixel electrode, a light emitting element arranged on the organic layer, including a semiconductor stack, a first protective layer, a contact electrode, and a second protective layer, a connection electrode connecting the light emitting element and the pixel electrode, wherein the first protective layer is an insulating protective layer, the second protective layer is a conductive protective layer, wherein the connection electrode and the second protective layer are etchable with the same etchant.

According to one or more embodiments, the second protective layer may be a conductive light-transmitting material.

According to one or more embodiments, wherein the contact electrode may include aluminum, wherein the second protective layer may include Indium Zinc Oxide (IZO), wherein the connection electrode may include at least one selected from among Indium Tin Oxide (ITO) and Indium Zinc Oxide (IZO).

According to one or more embodiments, wherein the contact electrode may be arranged on one side of the semiconductor stack and may cover the one side while being spaced apart from a top surface of the semiconductor stack by a first distance.

According to one or more embodiments, the second protective layer may be arranged on the one side of the semiconductor stack and may cover the one side while being spaced apart from the top surface of the semiconductor stack by a second distance, and the second distance may be further than the first distance.

According to one or more embodiments, the connection electrode may be on the one side of the semiconductor stack, is may be arranged further away from the semiconductor stack than the second protective layer and may be spaced apart from the top surface of the semiconductor stack by a third distance, wherein the third distance may be further than the first distance.

According to one or more embodiments, the second distance and the third distance may be the same and thicknesses of the second protective layer and the connecting electrode may be the same.

According to one or more embodiments, the second distance may be closer than the third distance and a thickness of the second protective layer may be thicker than a thickness of the connection electrode.

According to one or more embodiments, the third distance may be closer than the second distance and a thickness of the connection electrode may be thicker than the thickness of the second protective layer.

According to one or more embodiments, the second protective layer may be arranged on the one side of the semiconductor stack to cover the one side, may be further away from the semiconductor stack than the contact electrode, may cover the top surface of the contact electrode, and may be spaced apart from the top surface of the semiconductor stack by a second distance, and the second distance may be closer than the first distance.

According to one or more embodiments, the connection electrode may be on the one side of the semiconductor stack, may be further away from the semiconductor stack than the second protective layer and may be arranged at a third distance from the top surface of the semiconductor stack, and the third distance may be equal to the second distance.

According to one or more embodiments, the connection electrode may not be in direct contact with the contact electrode and may be electrically connected through the second protective layer.

According to one or more embodiments, the second protective layer may be in direct contact with the organic layer.

According to one or more embodiments, the semiconductor stack may further include, a first semiconductor layer arranged on the organic layer and including a semiconductor material layer doped with a first conductive dopant, an active layer arranged on the first semiconductor layer, and a second semiconductor layer arranged on the active layer and including a semiconductor material layer doped with a second conductive dopant.

According to one or more embodiments of the present disclosure, a method of manufacturing a display device includes forming a light emitting element including a semiconductor stack, a first protective layer, a contact electrode, and a second protective layer on a semiconductor substrate, wherein the first protective layer is an insulating protective layer, and the second protective layer is a conductive protective layer, bonding the light emitting element on a circuit board including a pixel electrode, depositing an electrode material layer on an entire surface of the circuit board, and then etching a portion of the electrode material layer and a portion of the second protective layer with the same etchant using a mask pattern.

According to one or more embodiments, the bonding the light emitting element may include forming an organic layer on the pixel electrode and performing a first cure, transferring the light emitting element onto the organic layer and performing a second cure, wherein the second protective layer may have a crystallization temperature higher than a second curing temperature of the organic layer.

According to one or more embodiments, the second curing temperature may be a temperature of 200° C. or more and 250° C. or less, and the second protective layer may be Indium Zinc Oxide (IZO).

According to one or more embodiments, the bonding the light emitting element may include transferring the light emitting element formed on the semiconductor substrate to a relay substrate, transferring the light emitting element on the relay substrate to a transfer substrate, and then transferring the light emitting element on the transfer substrate to the circuit board.

According to one or more embodiments, the transfer substrate to which the light emitting element is transferred may be cleaned with a chemical solution, and the chemical solution may peel off the contact electrode and may not react with the second protective layer.

According to one or more embodiments, the etching a portion of the electrode material layer and a portion of the second protective layer with the same etchant may include forming a mask pattern so that a photoresist covers a side surface of the contact electrode, and etching the electrode material layer and the second protective layer on an upper portion of the light emitting element exposed by the mask pattern, wherein the etched electrode material layer may form a connection electrode, and wherein a height of the second protective layer and a height of the connection electrode may be determined according to a height of the photoresist.

According to one or more embodiments of the present disclosure, an electronic device includes a display device including a substrate, a pixel electrode arranged on the substrate, an organic layer arranged on the pixel electrode, a light emitting element arranged on the organic layer, the light emitting element including a semiconductor stack, a first protective layer, a contact electrode, and a second protective layer, and a connection electrode connecting the light emitting element and the pixel electrode, wherein the first protective layer is an insulating protective layer, the second protective layer is a conductive protective layer, wherein the connection electrode and the second protective layer are etchable with the same etchant.

According to one or more embodiments of the present disclosure, it is possible to increase the light emission rate of the light emitting element and increase the brightness of the display device by increasing the reflectivity of light emitted by the bottom surface of the light emitting element.

### BRIEF DESCRIPTION OF THE DRAWINGS

The above and other aspects and features of the present disclosure will become more apparent by describing in more detail embodiments thereof with reference to the attached drawings, in which:

FIG. 1 is a perspective view illustrating a display device according to one or more embodiments.

FIG. 2 is a layout drawing illustrating a display device according to one or more embodiments.

FIG. 3 is a block drawing illustrating a display device according to one or more embodiments.

FIG. 4 is an equivalent circuit drawing illustrating a sub-pixel according to one or more embodiments.

FIG. 5 is a layout diagram illustrating pixels in a display area according to one or more embodiments.

FIG. 6 is a cross-sectional view illustrating an example of a cross-section of a display panel corresponding to lines I-l′in FIG. 5.

FIG. 7 is a cross-sectional view illustrating an example of area A1 of FIG. 6 in more detail.

FIG. 8 is a cross-sectional view illustrating an example of area B of FIG. 7 in more detail.

FIG. 9 is a cross-sectional view illustrating another example of area B of FIG. 7 in more detail.

FIG. 10 is a cross-sectional view illustrating another example of area B of FIG. 7 in more detail.

FIG. 11 is a cross-sectional view illustrating another example of area B of FIG. 7 in more detail.

FIG. 12 is a schematic diagram illustrating light emitted from a light emitting element in one or more embodiments of FIG. 7.

FIG. 13 is a graph illustrating reflectivity (or reflectance) for (e.g., relative to) wavelengths of aluminum, chromium, and gold.

FIG. 14 is a flow chart illustrating a method for manufacturing a display device according to one or more embodiments.

FIGS. 15-33 are example diagrams to illustrate a method of manufacturing a display device according to one or more embodiments.

FIG. 34 is an example perspective view of a smart watch including a display device according to one or more embodiments.

FIGS. 35 and 36 are example perspective views of a virtual reality (VR) device including a display device according to one or more embodiment.

FIG. 37 is an example perspective view of a VR device including a display device according to one or more embodiments.

FIG. 38 is an example perspective view illustrating a vehicle instrument cluster and center fascia including display devices according to one or more embodiments.

FIG. 39 is an example perspective view of a transparent display device including a display device according to one or more embodiments.

### DETAILED DESCRIPTION

Aspects and features of embodiments of the present disclosure and methods of accomplishing the same may be understood more readily by reference to the detailed description of embodiments and the accompanying drawings. Hereinafter, aspects of some embodiments will be described in more detail with reference to the accompanying drawings. The described embodiments, however, may be embodied in one or more suitable different forms, and should not be construed as being limited to only the illustrated embodiments herein. Rather, these embodiments are provided as examples so that the present disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure might not be described, and/or redundant descriptions thereof may not be provided.

Unless otherwise noted, like reference numerals, characters, or combinations thereof denote like elements throughout the attached drawings and the written description, and thus, duplicative descriptions thereof may not be provided. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching and/or shading conveys or indicates any preference or requirement for particular materials, material properties, dimensions, proportions, commonalities between illustrated elements, and/or any other characteristic, attribute, property, and/or the like, of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural and/or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in one or more suitable different ways, all without departing from the spirit and/or scope of the present disclosure.

In the detailed description, for the purposes of explanation, numerous specific details are set forth to provide a thorough understanding of one or more embodiments. It is apparent, however, that one or more embodiments may be practiced without these specific details or with one or more equivalent arrangements. In other instances, well-known structures and devices (e.g., those that should be readily understood by those of ordinary skill in the art) are shown in block diagram form to avoid unnecessarily obscuring the present embodiments.

Spatially relative terms, such as “beneath,” “below,” “lower,” “under,” “above,” “upper,” and/or the like, may be used herein for ease of explanation to describe one element or feature's relationship to another element(s) or feature(s) as illustrated in the drawings. It will be understood that the spatially relative terms are intended to encompass different orientations of the device in use or in operation, in addition to the orientation depicted in the drawings. For example, if the device in the drawings is turned over, elements described as “below” or “beneath” or “under” other elements or features would then be oriented “above” the other elements or features. Thus, the example terms “below” and “under” can encompass both (e.g., simultaneously) an orientation of above and below. The device may be otherwise oriented (e.g., rotated 90 degrees or at other orientations) and the spatially relative descriptors used herein should be interpreted accordingly. Similarly, if (e.g., when) a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” refers to viewing a target portion from the top, and the phrase “on a cross-section” refers to viewing a cross-section formed by vertically cutting a target portion from the side.

It will be understood that if (e.g., when) an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, if (e.g., when) a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. In one or more embodiments, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of the present disclosure, expressions such as “at least one of,” “one of,” and “selected from among,” when preceding a list of elements, modify the entire list of elements and do not modify the individual elements of the list. For example, “at least one of X, Y, and Z,” “at least one of X, Y, or Z,” “at least one selected from among X, Y, and Z” and “at least one selected from among the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

It will be understood that, although the terms “first,” “second,” “third,” and/or the like, may be used herein to describe one or more suitable elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As used herein, the terms “use,” “using,” and “used” may be considered synonymous with the terms “utilize,” “utilizing,” and “utilized,” respectively.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

When one or more embodiments may be implemented differently, a specific process order may be performed differently from the described order. For example, two consecutively described processes may be performed substantially at the same time (e.g., concurrently) or performed in an order opposite to (or different from) the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112 (a) and 35 U.S.C. § 132(a).

The electronic or electric devices and/or any other relevant devices or components according to one or more embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, and/or the like. Also, a person of skill in the art should recognize that the functionality of one or more suitable computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

A person of ordinary skill in the art would appreciate, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

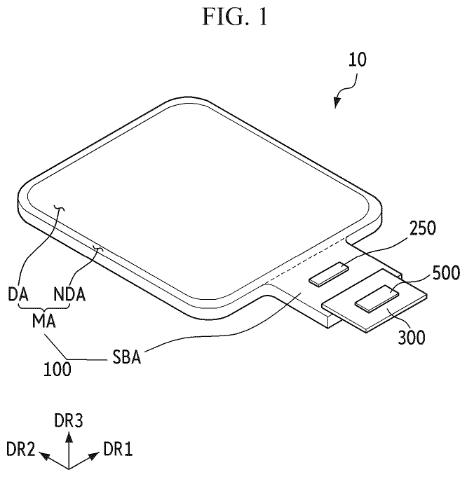

FIG. 1 is a perspective view illustrating a display device according to one or more embodiments.

Referring to FIG. 1, a display device 10 is a device for displaying video and/or still images, such as mobile phones, smart phones, tablet personal computers, and/or portable electronic devices such as smart watches, watch phones, mobile communication terminals, electronic notebooks, e-books, portable multimedia players (PMP), navigation, and/or ultra mobile PC (UMPC), as well as display screens for a variety of products such as televisions, laptops, monitors, billboards, and/or the internet of things (IOT).

The display device 10 may be a light emitting display device, such as an organic light-emitting display device utilizing an organic light-emitting diode, a quantum dot light-emitting display device including a quantum dot light-emitting layer, an inorganic light-emitting display device including an inorganic semiconductor, and/or a miniaturized light-emitting display device utilizing a micro or nano light emitting diode (micro LED or nano LED). Hereinafter, the description focuses on the embodiments in which the display device 10 is a micro-light emitting display device, but the present disclosure is not limited thereto. In some embodiments, hereinafter, an ultra-small (e.g., micro) light emitting diode is described as a light emitting element for convenience of explanation.

The display device 10 includes a display panel 100, a display driving circuit 250, a circuit board 300, and a power supply circuit 500.

The display panel 100 may be formed as a rectangular shaped plane having a short side in the first direction DR1 and a long side in the second direction DR2 that intersects the first direction DR1. A corner where the short side in the first direction DR1 and the long side in the second direction DR2 meet may be rounded to have a set or predetermined curvature or may be formed at a right angle. The planar shape of the display panel 100 is not limited to a rectangle, but may be formed in other suitable polygonal, circular, or oval shapes. The display panel 100 may be formed flat or substantially flat but the present disclosure is not limited thereto. In some embodiments, the display panel 100 may be formed at the left and right ends and may include curved portions with a constant curvature or a changing curvature (e.g. the left and/or right end portions of the display panel 100 may be curved). In one or more embodiments, the display panel 100 may be flexibly formed to be bent, curved, bent, folded, or rolled.

The substrate SUB of the display panel 100 may include a main area MA and a sub area SBA.

The main area MA may include a display area DA that is to display an image and a non-display area NDA that is around (e.g., surrounding) the display area DA. The display area DA may include a plurality of pixels that are to display an image. Each pixel may include a plurality of sub-pixels. For example, each of the pixels may include a first sub-pixel that is to emit light of a first color, a second sub-pixel that is to emit light of a second color, and a third sub-pixel that is to emit light of a third color. However, the embodiments of the present disclosure are not limited thereto.

The sub-area SBA may protrude from one side of the main area MA in the second direction DR2. Although FIG. 1 illustrates the sub-area SBA being unfolded, the sub-area SBA may be bent, and in this case, may be arranged on the lower surface of the display panel 100. When the sub-area SBA is bent, it may overlap the main area MA in the third direction DR3, which is the thickness direction of the display panel 100. The display driving circuit 250 may be arranged in the sub-area SBA.

The display driving circuit 250 may generate signals and voltages for driving the display panel 100. The display driving circuit 250 may be formed as an integrated circuit (IC) and attached to the display panel 100 using a chip on glass (COG) method, a chip on plastic (COP) method, and/or an ultrasonic bonding method, but the present disclosure is not limited thereto. In one or more embodiments, the display driving circuit 250 may be attached to the circuit board 300 using a chip on film (COF) method.

The circuit board 300 may be attached to one end of the sub-area SBA of the display panel 100. As such, the circuit board 300 may be electrically connected to the display panel 100 and the display driving circuit 250. The display panel 100 and the display driving circuit 250 may receive digital video data, timing signals, and/or driving voltages through the circuit board 300. The circuit board 300 may be a flexible film, such as a flexible printed circuit board, a printed circuit board, and/or a chip on film.

The power supply circuit 500 may generate a plurality of panel driving voltages according to an external power supply voltage. The power supply circuit 500 may be formed as an integrated circuit (IC) and attached to the circuit board 300 using a COF method.

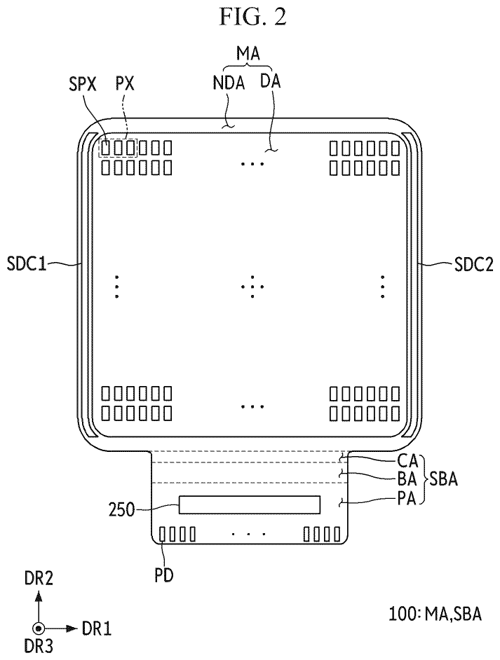

FIG. 2 is a layout drawing illustrating a display device according to one or more embodiments. FIG. 2 illustrates that the sub-area SBA is unfolded without being bent.

Referring to FIG. 2, the display panel 100 may include the main area MA and the sub-area SBA.

The main area MA may include the display area DA that is to display an image and the non-display area NDA that is a peripheral area of the display area DA. The display area DA may occupy most of the main area MA. The display area DA may be placed substantially in the center of the main area MA.

The display area DA may include a plurality of pixels PX for displaying an image, and each of the plurality of pixels PX may include a plurality of sub-pixels SPX. A pixel PX may be defined as a sub-pixel group of the smallest unit capable of expressing a white grayscale (e.g., capable of expressing grayscale images, including white color by way of maximum lightness within the grayscale image).

The non-display area NDA may be placed adjacent to the display area DA. The non-display area NDA may be an area outside the display area DA. The non-display area NDA may be arranged to surround the display area DA. The non-display area NDA may be an edge area of the display panel 100.

A first scan driving portion SDC1 and a second scan driving portion SDC2 may be arranged in the non-display area NDA. The first scan driving portion SDC1 may be arranged on one side (e.g., the left side) of the display panel 100, and the second scan driving portion SDC2 may be arranged on the other side (e.g., the right side) of the display panel 100. However, the embodiments of the present disclosure are not limited thereto.

Each of the first scan driving portion SDC1 and the second scan driving portion SDC2 may be electrically connected to the display driving circuit 250 through scan fan out lines. Each of the first scan driving portion SDC1 and the second scan driving portion SDC2 may receive a scan control signal from the display driving circuit 250, generate scan signals according to the scan control signal, and output them to scan lines.

The sub-area SBA may protrude from one side of the main area MA in the second direction DR2. The length of the sub-area SBA in the second direction DR2 may be smaller than the length of the main area MA in the second direction DR2. The length in the first direction DR1 of the sub area SBA may be less than the length in the first direction DR1 of the main area MA or may be substantially equal to the length in the first direction DR1 of the main area MA. The sub-area SBA may be curved and may be arranged at a lower portion of the display panel 100. In this case, the sub-area SBA may overlap the main area MA in the third direction DR3.

The sub-area SBA may include a connection area CA, a pad area PA, and a bending area BA.

The connection area CA is an area protruding from one side of the main area MA in the second direction DR2. One side of the connection area CA may be in contact with the non-display area NDA of the main area MA, and the other side of the connection area CA may be in contact with the bending area BA.

The pad area PA is an area where the pads PD and the display driving circuit 250 are arranged. The display driving circuit 250 may be attached to the driving pads of the pad area PA using a conductive adhesive member such as an anisotropic conductive film. The circuit board 300 may be attached to the pads PD of the pad area PA using a conductive adhesive member such as an anisotropic conductive film. One side of the pad area PA may be in contact with the bending area BA.

The bending area BA is a bent area. When the bending area BA is bent, the pad area PA may be arranged below the connection area CA and below the main area MA. The bending area BA may be arranged between the connection area CA and the pad area PA. One side of the bending area BA may be in contact with the connection area CA, and the other side of the bending area BA may be in contact with the pad area PA.

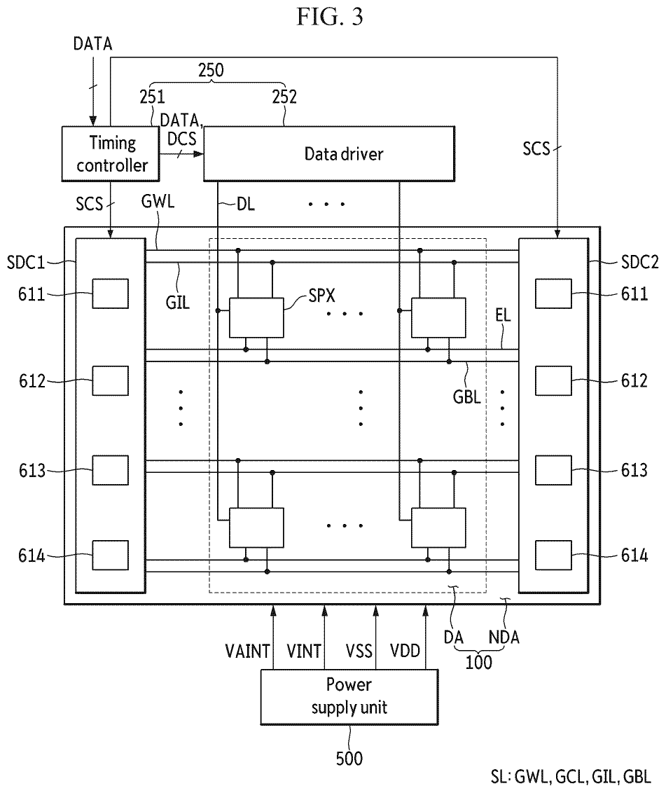

FIG. 3 is a block drawing illustrating a display device according to one or more embodiments.

Referring to FIG. 3, the display area DA includes a plurality of pixels PX, a plurality of scan lines SL, a plurality of emission control lines EL, and a plurality of data lines DL.

The plurality of pixels PX may be arranged in a matrix form in the first direction DR1 and the second direction DR2. The plurality of scan lines SL and the plurality of emission control lines EL may extend in the first direction DR1 and be arranged in the second direction DR2. The plurality of data lines DL may extend in the second direction DR2 and be arranged in the first direction DR1. The plurality of scan lines SL may include a a plurality of write scan lines GWL, a plurality of control scan lines GCL, a plurality of initialization scan lines GIL, and a plurality of bias scan lines GBL.

Each of the plurality of sub-pixels SPX may be connected to a write scan line GWL from among the plurality of write scan lines GWL, a control scan line GCL from among the plurality of control scan lines GCL, an initialization scan line GIL from among the plurality of initialization scan lines GIL, a bias scan line GBL from among the plurality of bias scan lines GBL, an emission control line EL from among the plurality of emission control lines EL, and a data line DL from among the plurality of data lines DL. Each of the plurality of sub-pixels SPX may be supplied with a data voltage of the data line DL according to the write scan signal of the write scan line GWL and may be to emit light emitting elements according to the data voltage.

The non-display area NDA includes a first scan driving portion SDC1, a second scan driving unit SDC2, and a display driving circuit 250.

Each of the first scan driving portion SDC1 and the second scan driving portion SDC2 may include a write scan signal output portion 611, a control scan signal output portion 612, an initialization scan signal output portion 613, a bias scan signal output portion 614, and a light emitting signal output portion 615. Each of the write scan signal output portion 611, the control scan signal output portion 612, the initialization scan signal output portion 613, the bias scan signal output portion 614, and the light emitting signal output portion 615 may receive a scan timing control signal SCS from a timing control circuit 251. The write scan signal output portion 611 may generate write scan signals according to the scan timing control signal SCS of the timing control circuit 251 and sequentially output them to the write scan lines GWL. The control scan signal output portion 612 may generate control scan signals according to the scan timing control signal SCS and sequentially output them to the control scan lines GCL. The initialization scan signal output portion 613 may generate initialization scan signals according to the scan timing control signal SCS and sequentially output them to the initialization scan lines GIL. The bias scan signal output portion 614 may generate bias scan signals according to the scan timing control signal SCS and sequentially output them to the bias scan lines EBL. The light emitting signal output portion 615 may generate light emitting control signals according to the scan timing control signal SCS and sequentially output them to the emission control lines EL.

The display driving circuit 250 includes the timing control circuit 251 and a data driving circuit 252.

The data driving circuit 252 may receive digital video data DATA and a data timing control signal DCS from the timing control circuit 251. The data driving circuit 252 converts digital video data DATA into analog data voltages according to the data timing control signal DCS and outputs them to the data lines DL. In this case, the sub-pixels SPX are selected by the write scan signals of the first scan driving unit SDC1 and the second scan driving unit SDC2, and data voltages may be supplied to the selected sub-pixels SPX.

The timing control circuit 251 may receive digital video data and timing signals from an external source. The timing control circuit 251 may generate the scan timing control signal SCS and the data timing control signal DCS to control the display panel 100 according to timing signals. The timing control circuit 251 may output the scan timing control signal SCS to the first scan driving unit SDC1 and the second scan driving unit SDC2. The timing control circuit 251 may output digital video data DATA and a data timing control signal DCS to the data driving circuit 252.

The power supply circuit 500 may generate a plurality of panel driving voltages according to an external power supply voltage. For example, the power supply circuit 500 may generate and supply a first driving voltage VDD, a second driving voltage VSS, and a third driving voltage VINT to the display panel 100.

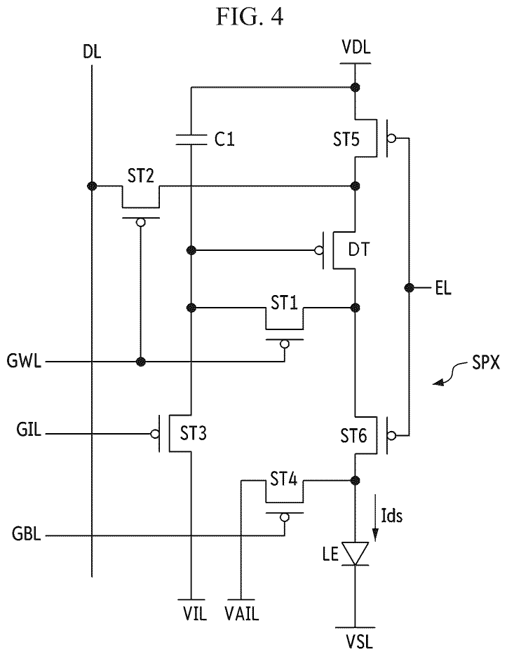

FIG. 4 is an equivalent circuit drawing illustrating a sub-pixel according to one or more embodiments.

Referring to FIG. 4, the sub-pixel SPX according to one or more embodiments may be connected to scan lines GWL, GIL, GCL, and GBL, an emission line EL, and a data line DL. For example, the sub-pixel SPX may be connected to the write scan line GWL, the initialization scan line GIL, the control scan line GCL, the bias scan line GBL, the emission line EL, and the data line DL.

The sub-pixel SPX according to one or more embodiments includes a driving transistor DT, switch elements, a capacitor C1, and a light emitting element LE. The switch elements include first to sixth transistors ST1, ST2, ST3, ST4, ST5, and ST6. The driving transistor DT, switch elements, and capacitor C1 may be referred to as a pixel circuit PXC.

The driving transistor DT includes a gate electrode, a conductive layer, and a second electrode. The driving transistor DT controls the drain-source current (Ids, hereinafter referred to as “driving current”) flowing between the conductive layer and the second electrode according to the data voltage applied to the gate electrode.

The light emitting element LE may be a micro light emitting diode.

The light emitting element LE may emit light according to the driving current Ids. The amount of light emitted from the light emitting element LE may be proportional to the driving current Ids. The anode electrode of the light emitting element LE is connected to the conductive layer of the fourth transistor ST4 and the second electrode of the sixth transistor ST6, and the cathode electrode may be connected to a second power supply line VSL to which a second power voltage is applied.

The capacitor C1 is formed between the second electrode of the driving transistor DT and the first power supply line VDL to which the first power supply voltage is applied. The first power supply voltage may be at a higher level than the second power supply voltage. One electrode of the capacitor C1 may be connected to the second electrode of the driving transistor DT, and the other electrode may be connected to the first power supply line VDL.

As shown in FIG. 4, the first to sixth transistors ST1, ST2, ST3, ST4, ST5, and ST6 and the driving transistor DT may all be formed as p-type metal-oxide-semiconductor field-effect transistor (MOSFET). For example, the active layer of each of the first to sixth transistors ST1, ST2, ST3, ST4, ST5, and ST6 and the driving transistor DT may be formed of polysilicon.

The gate electrode of the first transistor ST1 and the gate electrode of the second transistor ST2 may be connected to the write scan line GWL, and the gate electrode of the third transistor ST3 may be connected to the initialization scan line GIL, and the gate electrode of the fourth transistor ST4 may be connected to the bias scan line GBL. Because the first to sixth transistors ST1, ST2, ST3, ST4, ST5, and ST6 are formed as p-type MOSFET, they may be turned on if (e.g., when) a scan signal and an emission signal with a gate suitably low voltage are applied to the control scan line GCL, the initialization scan line GIL, the write scan line GWL, the bias scan line GBL, and the emission line EL, respectively. One electrode of the third transistor ST3 and one electrode of the fourth transistor ST4 may be connected to the initialization voltage line VIL.

In one or more embodiments, the driving transistor DT, the second transistor ST2, the fourth transistor ST4, the fifth transistor ST5, and the sixth transistor ST6 may be formed of a p-type MOSFET, and the first transistor ST1 and the third transistor ST3 may be formed of an n-type MOSFET. The active layers of each of the driving transistor DT, the second transistor ST2, the fourth transistor ST4, the fifth transistor ST5, and the sixth transistor ST6 formed of p-type MOSFETs may be formed of polysilicon, the active layers of each of the first transistor ST1 and the third transistor ST3 formed of an n-type MOSFET may be formed of an oxide semiconductor.

In some embodiments, because the first transistor ST1 and the third transistor ST3 are formed as n-type MOSFET, the first transistor ST1 may be turned on when a scan signal of the gate suitably high voltage is applied, and the third transistor ST3 may be turned on when an initialization scan signal of the gate suitably high voltage is applied. In contrast, the second transistor ST2, the fourth transistor ST4, the fifth transistor ST5, and the sixth transistor ST6 are formed as p-type MOSFET, so they may be turned on when a scan signal of the gate suitably low voltage and a light emission signal are applied.

In one or more embodiments, the fourth transistor ST4 may be formed of an n-type MOSFET, so that each active layer of the fourth transistor ST4 may be formed of an oxide semiconductor. When the fourth transistor ST4 is formed of an n-type MOSFET, it may be turned on when a scan signal of the gate suitably high voltage is applied.

In one or more embodiments, the first to sixth transistors ST1, ST2, ST3, ST4, ST5, and ST6 and the driving transistor DT may all be formed as n-type MOSFET. In this case, the active layer of each of the first to sixth transistors ST1, ST2, ST3, ST4, ST5, and ST6 and the driving transistor DT may be formed of an oxide semiconductor.

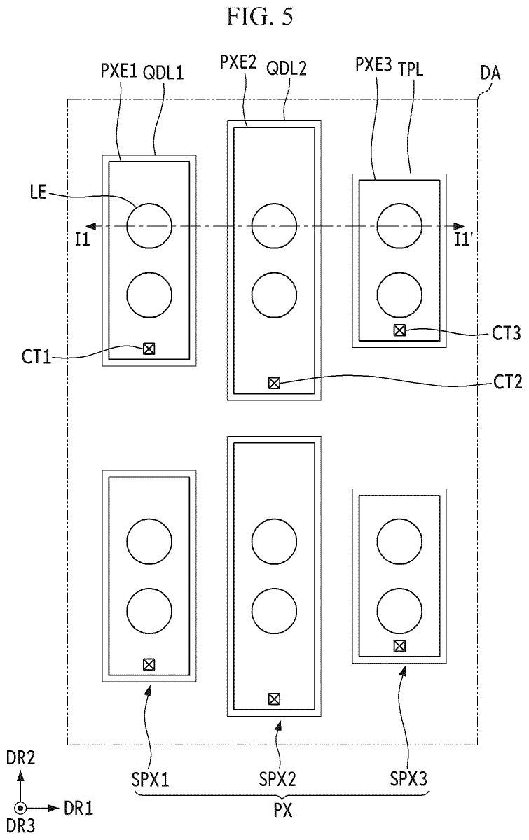

FIG. 5 is a layout diagram illustrating pixels in a display area according to one or more embodiments.

Referring to FIG. 5, each of the plurality of pixels PX of the display area DA may include three sub-pixels SPX1, SPX2, and SPX3, but the embodiments of the present disclosure are not limited thereto and may include four sub-pixels, for example. When each of the plurality of pixels PX includes three sub-pixels SPX1, SPX2, and SPX3, the first sub-pixel SPX1, the second sub-pixel SPX2, and the third sub-pixel SPX3 may include.

The plurality of pixels PX may be arranged in a matrix form. In each of the plurality of pixels PX, the first sub-pixel SPX1, the second sub-pixel SPX2, and the third sub-pixel SPX3 may be arranged in a first direction DR1.

When each of the plurality of pixels PX includes three sub-pixels SPX1, SPX2, and SPX3, the first sub-pixel SPX1 may be to emit light of a first wavelength (e.g., a first light), and the second sub-pixel SPX2 may be to emit light of a second wavelength (e.g., a second light), and the third sub-pixel SPX3 may be to emit light of a third wavelength (e.g., a third light). Here, the first light may be light in a red wavelength band, the second light may be light in a green wavelength band, and the third light may be light in a blue wavelength band. For example, the blue wavelength band may refer to light having a main peak wavelength in the wavelength band from approximately 370 nm to 460 nm, the green wavelength band may refer to light having a main peak wavelength in the wavelength band from approximately 480 nm to 560 nm, and the red wavelength band may refer to light having a main peak wavelength in the wavelength band from approximately 600 nm to 750 nm.

In one or more embodiments, if (e.g., when) each of the plurality of pixels PX includes four sub-pixels, the first sub-pixel may be to emit light of a first wavelength, the second and fourth sub-pixels may be to emit light of a second wavelength, and the third sub-pixel may be to emit light of a third wavelength. In one or more embodiments, the first sub-pixel may be to emit light of a first wavelength, the second sub-pixel may be to emit light of a second wavelength, the third sub-pixel may be to emit light of a third wavelength, and the fourth sub-pixel may be to emit light of a fourth wavelength (e.g., a fourth light). In this case, the fourth light may be white light.

The first sub-pixel SPX1 includes a first pixel electrode PXE1, a plurality of light emitting elements LE, and a first light conversion layer QDL1. The second sub-pixel SPX2 includes a second pixel electrode PXE2, a plurality of light emitting elements LE, and a second light conversion layer QDL2. The third sub-pixel SPX3 includes a third pixel electrode PXE3, a plurality of light emitting elements LE, and a light transmission layer TPL.

Each of the first pixel electrode PXE1, the second pixel electrode PXE2, and the third pixel electrode PXE3 may have a rectangular planar shape having a short side in the first direction DR1 and a long side in the second direction DR2. The area of the first sub-pixel SPX1, the area of the second sub-pixel SPX2, and the area of the third sub-pixel SPX3 may be set according to the light conversion efficiency of the first light conversion layer QDL1 and the light conversion efficiency of the second light conversion layer QDL2. For example, the area of the respective sub-pixel may become larger as the light conversion efficiency decreases.

For example, as shown in FIG. 5, when the light conversion efficiency of the second light conversion layer QDL2 is lower than the light conversion efficiency of the first light conversion layer QDL1, the area of the second pixel electrode PXE2 may be larger than the area of the first pixel electrode PXE1. Also, because the light transmission layer TPL directly transmits the light of the light emitting element LE, whereas the first light conversion layer QDL1 may convert the light, the area of the first pixel electrode PXE1 may be larger than the area of the third pixel electrode PXE3.

Each of the pixel electrodes PXE1, PXE2, and PXE3 may be electrically connected to at least one transistor through the pixel connection hole CT1, CT2, and CT3, respectively. For example, each of the pixel electrodes PXE1, PXE2, and PXE3 may be electrically connected to the second electrode of the fourth transistor (ST4 in FIG. 4) and the second electrode of the sixth transistor (ST6 in FIG. 4) of the corresponding sub-pixel.

The plurality of light emitting elements LE may be arranged on each of the pixel electrodes PXE1, PXE2, and PXE3. The same number of light emitting elements LE may be arranged on each of the pixel electrodes PXE1, PXE2, and PXE3. For example, two light emitting elements LE may be arranged on each of the pixel electrodes PXE1, PXE2, and PXE3. The plurality of light emitting elements LE may be to emit third light, for example, light in a blue wavelength band, but the embodiments of the present disclosure are not limited thereto. When the light emitting element LE of the first sub-pixel SPX1 emits first light, the light emitting element LE of the second sub-pixel SPX2 emits second light, and the light emitting element LE of the third sub-pixel SPX3 emits third light, the light conversion layers QDL1 and QDL2 and the light transmission layer TPL may not be provided.

The first light conversion layer QDL1 may completely overlap the first pixel electrode PXE1 and the plurality of light emitting elements LE of the first sub-pixel SPX1. The area of the first light conversion layer QDL1 may be larger than the area of the first pixel electrode PXE1. The first light conversion layer QDL1 may convert and/or shift the peak wavelength of incident light into light of another set or specific peak wavelength and emit it. For example, the first light conversion layer QDL1 may convert and/or shift the third light emitted from the plurality of light emitting elements LE of the first sub-pixel SPX1 into first light.

The second light conversion layer QDL2 may completely overlap the plurality of light emitting elements LE of the second pixel electrode PXE2 and the second sub-pixel SPX2. The area of the second light conversion layer QDL2 may be larger than the area of the second pixel electrode PXE2. The second light conversion layer QDL2 may convert and/or shift the peak wavelength of incident light into light of another set or specific peak wavelength and emit it. For example, the second light conversion layer QDL2 may convert and/or shift the third light emitted from the plurality of light emitting elements LE of the second sub-pixel SPX2 into second light.

The light transmission layer TPL may completely overlap the plurality of light emitting elements LE of the third pixel electrode PXE3 and the third sub-pixel SPX3. The light transmission layer TPL may be to transmit incident light as it is. For example, the light transmission layer TPL may directly transmit the third light emitted from the plurality of light emitting elements LE of the third sub-pixel SPX3.

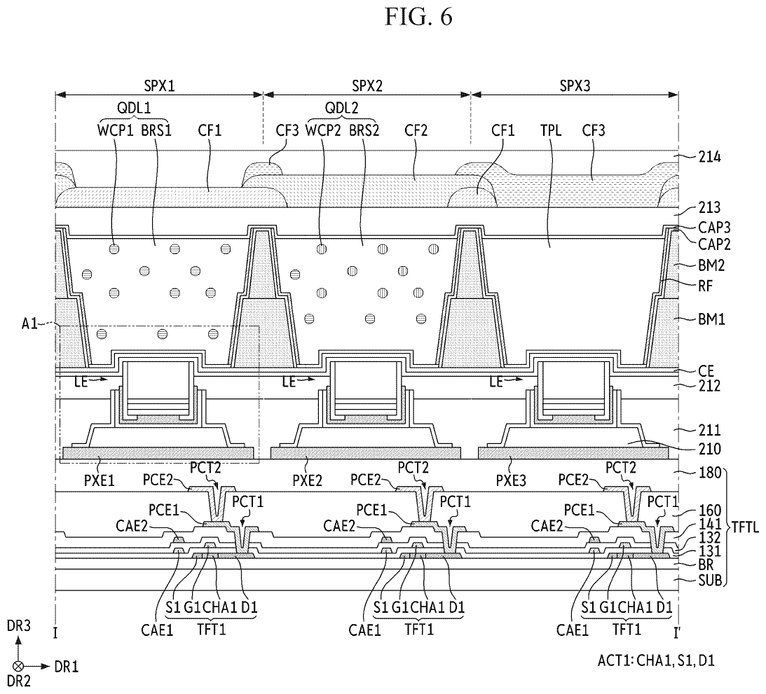

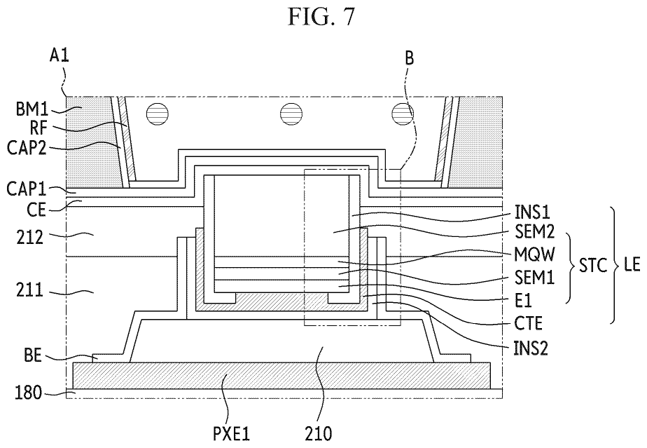

FIG. 6 is a cross-sectional view illustrating an example of a cross-section of a display panel corresponding to lines I-l′in FIG. 5. FIG. 7 is a cross-sectional view illustrating an example of area A1 of FIG. 6 in more detail.

Referring to FIGS. 6 and 7, a substrate SUB may be made of an insulating material such as glass, polymer resin, and/or the like. If the substrate SUB is made of polymer resin, it may be a flexible substrate that may be stretched. The polymer resin may be acrylic resin, epoxy resin, phenolic resin, polyamide resin, polyimide resin, and/or the like.

A barrier film BR may be arranged on the substrate SUB. The barrier film BR may protect the transistors of the thin film transistor layer TFTL and the light emitting elements LE arranged on the thin film transistor layer TFTL from moisture penetrating through the substrate SUB, which is vulnerable to moisture penetration. The barrier film BR may be composed of a plurality of inorganic films stacked alternately with each other.

A thin film transistor TFT1 may be arranged on the barrier film BR. The thin film transistor TFT1 may be either the fourth transistor ST4 or the sixth transistor ST6 shown in FIG. 4. The thin film transistor TFT1 may include a first active layer ACT1 and a first gate electrode G1.

The first active layer ACT1 of the thin film transistor TFT1 may be arranged on the barrier film BR. The first active layer ACT1 of the thin film transistor TFT1 may include polycrystalline silicon, monocrystalline silicon, low-temperature polycrystalline silicon, and/or amorphous silicon. In one or more embodiments, the first active layer ACT1 of the thin film transistor TFT1 may include an oxide semiconductor including IGZO (indium (In), gallium (Ga), zinc (Zn), and oxygen (O)), IGZTO (indium (In), gallium (Ga), zinc (Zn), tin (Sn), and oxygen (O)), and/or IGTO (indium (In), gallium (Ga), tin (Sn), and oxygen (O)).

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be arranged on one side of the first channel area CHA1, and the first drain area D1 may be arranged on the other side of the first channel area CHA1. The first source area S1 and the first drain area D1 may be areas that do not overlap with the first gate electrode G1 in the third direction DR3. The first source area S1 and the first drain area D1 may be conductive areas in which semiconductor materials are doped with ions.

A first gate insulating film 131 may be arranged on the first channel area CHA1, the first source area S1, and the first drain area D1 of the thin film transistor TFT1.

A first gate metal layer may be arranged on a first gate insulating film 131. The first gate metal layer may include the first gate electrode G1 and the first capacitor electrode CAE1 of the thin film transistor TFT1. The first gate electrode G1 may overlap the first active layer ACT1 in the third direction DR3. In FIG. 6, the first gate electrode G1 and the first capacitor electrode CAE1 are shown to be arranged apart from each other. However, if the thin film transistor TFT1 is the driving transistor DT of

FIG. 4, the first gate electrode G1 and the first capacitor electrode CAE1 may be electrically and/or physically connected to each other. In one or more embodiments, if the thin film transistor TFT1 is any one of the first to sixth transistors (ST1 to ST6) of FIG. 4, the first gate electrode G1 and the first capacitor electrode CAE1 may not be electrically or physically connected to each other.

A second gate insulating film 132 may be arranged on the first gate electrode G1 and the first capacitor electrode CAE1 of the thin film transistor TFT1.

A second gate metal layer may be arranged on the second gate insulating film 132. The second gate metal layer may include a second capacitor electrode CAE2. The second capacitor electrode CAE2 may overlap the first capacitor electrode CAE1 of the thin film transistor TFT1 in the third direction DR3. Because the second gate insulating film 132 has a set or predetermined dielectric constant, the capacitor (C1 in FIG. 4) may be formed by the first capacitor electrode CAE1, the second capacitor electrode CAE2, and the second gate insulating film 132 arranged between them.

A first interlayer insulating film 141 may be arranged on the second capacitor electrode CAE2.

A first data metal layer may be arranged on the first interlayer insulating film 141. The first data metal layer may include a first source connection electrode PCE1. The first source connection electrode PCE1 may be connected to the first drain area D1 of the first active layer ACT1 through a first source contact hole PCT1 penetrating the first gate insulating film 131, the second gate insulating film 132, and the first interlayer insulating film 141.

A first planarization film 160 may be arranged on the first source connection electrode PCE1 to planarize a step (e.g., stepped portion) caused by the thin film transistor TFT1.

A second data metal layer may be arranged on the first planarization film 160. The second data metal layer may include a second source connection electrode

PCE2. The second source connection electrode PCE2 may be connected to the first source connection electrode PCE1 through a second source contact hole PCT2 penetrating the first planarization film 160.

A second planarization film 180 may be arranged on the second source connection electrode PCE2.

The barrier film BR, the first gate insulating film 131, the second gate insulating film 132, and the first interlayer insulating film 141 may each independently be formed from an inorganic film, for example, silicon nitride (SiNₓ, for example, Si₃N₄), silicon oxynitride (SiOₓN_{y}), silicon oxide (SiOₓ, for example, SiO₂), titanium oxide (TiOₓ, for example, TiO₂), and/or aluminum oxide (AlOₓ, for example, Al₂O₃).

The first gate metal layer, the second gate metal layer, the first data metal layer, and the second data metal layer may each independently be formed as a single layer or multiple layers of any one selected from among molybdenum (Mo), aluminum (Al), chromium (Cr), gold (Au), titanium (Ti), nickel (Ni), neodymium (Nd), copper (Cu), and alloys thereof.

The first planarization film 160 and the second planarization film 180 may each independently be formed of an organic film such as an acrylic resin, an epoxy resin, a phenolic resin, a polyamide resin, a polyimide resin, and/or the like.

A light emitting element layer may be arranged on the second planarization organic film 180. The light emitting element layer may include pixel electrodes PXE1, PXE2, PXE3, light emitting elements LE, a common electrode CE, and a first organic layer 210.

A pixel electrode layer may be arranged on the second planarization film 180. The pixel electrode layer may include a first pixel electrode PXE1, a second pixel electrode PXE2, and a third pixel electrode PXE3. Each of the pixel electrodes PXE1, PXE2, and PXE3 may be connected to a second source connection electrode PCE2 through a pixel connection hole (CT1, CT2, and CT3 of FIG. 5) penetrating the second planarization film 180. Each of the pixel electrodes PXE1, PXE2, and PXE3 may be connected to a first source area S1 or a first drain area D1 of a respective thin film transistor TFT1 through the first source connection electrode PCE1 and the second source connection electrode PCE2. Therefore, a voltage controlled or selected by the respective thin film transistor TFT1 may be applied to each of the pixel electrodes PXE1, PXE2, and PXE3.

The pixel electrode layer may be formed as a single layer or multiple layers of any one selected from among molybdenum (Mo), aluminum (Al), chromium (Cr), gold (Au), titanium (Ti), nickel (Ni), neodymium (Nd), copper (Cu), and alloys thereof. For example, the pixel electrodes PXE1, PXE2, and PXE3 may include a first layer made of titanium (Ti), a second layer made of aluminum (Al), and a third layer made of titanium (Ti).

A first organic layer 210 may be arranged on each of the pixel electrodes PXE1, PXE2, and PXE3. For example, at least a portion of the pixel electrodes PXE1, PXE2, and PXE3 may be arranged on the first organic layer 210. The first organic layer 210 may temporarily fix and/or adhere the plurality of light emitting elements LE to prevent or reduce the risk of the plurality of light emitting elements LE tilting, falling over, and/or collapsing during a process of transferring the plurality of light emitting elements LE to the display panel 100. For example, the first organic layer 210 may be a film for temporarily adhering the plurality of light emitting elements LE onto each of the pixel electrodes PXE1, PXE2, and PXE3. To facilitate the temporary adhesion, the thickness of the first organic layer 210 may be greater than the thickness of each of the pixel electrodes PXE1, PXE2, and PXE3.

The first organic layer 210 may be a photosensitive organic layer such as photoresist. In one or more embodiments, the first organic layer 210 may be formed from an acrylic resin, an epoxy resin, a phenolic resin, a polyamide resin, a polyimide resin, and/or the like.

The plurality of light emitting elements LE may be arranged on the first organic layer 210. In FIG. 6, each of the plurality of light emitting elements LE is illustrated as a vertical type or kind micro LED extending in the third direction DR3. The vertical type or kind micro LED may refer to an LED having a structure in which a first semiconductor layer SEM1, an active layer MQW, and a second semiconductor layer SEM2 are sequentially arranged in the third direction DR3, which is a vertical direction.

Each of the plurality of light emitting elements LE may have a rectangular cross-sectional shape. For example, each of the plurality of light emitting elements LE may have substantially the same width of the top surface and the width of the bottom surface but the present disclosure is not limited thereto. For example, each of the plurality of light emitting elements LE may have a trapezoidal shape (e.g., an inverted trapezoidal shape) in which the width of the top surface is narrower than the width of the bottom surface.

Each of the plurality of light emitting elements LE may be formed of an inorganic material such as gallium nitride (GaN). Each of the plurality of light emitting elements LE may have a length in the first direction DR1, a length in the second direction DR2, and a length in the third direction DR3 of several μm to several hundred μm, respectively. For example, each of the plurality of light-emitting elements LE may have a length in the first direction DR1, a length in the second direction DR2, and a length in the third direction DR3 of approximately 100 um or less, respectively.

Each of the plurality of light emitting elements LE may be formed by growing on a semiconductor substrate, such as a silicon substrate and/or a sapphire substrate. The plurality of light emitting elements LE may be transferred directly from a semiconductor substrate onto pixel electrodes PXE1, PXE2, and PXE3 of a display panel 100. In one or more embodiments, the plurality of light emitting elements LE may be transferred onto pixel electrodes PXE1, PXE2, and PXE3 of a display panel 100 through an electrostatic method using an electrostatic head and/or a stamp method using an elastic polymer material such as PDMS (polydimethylsiloxane) and/or silicon as a transfer substrate.

The light emitting element LE may include a conductive layer E1, a semiconductor stack STC, a contact electrode CTE, and a first protective layer INS1. The semiconductor stack STC may include the first semiconductor layer SEM1, the active layer MQW, and the second semiconductor layer SEM2 that are sequentially arranged in the third direction DR3.

The conductive layer E1 may be arranged on the bottom surface of the first semiconductor layer SEM1. Although FIG. 7 illustrates that the conductive layer E1 covers the entire lower surface of the first semiconductor layer SEM1, the embodiments of the present disclosure are not limited thereto. In some embodiments, the conductive layer E1 may be arranged on a portion of the lower surface of the first semiconductor layer SEM1. The conductive layer E1 may include any one selected from among molybdenum (Mo), aluminum (AI), chromium (Cr), gold (Au), titanium (Ti), nickel (Ni), neodymium (Nd), and copper (Cu).

The first semiconductor layer SEM1 may be arranged on the contact electrode CTE. A length of the bottom surface of the first semiconductor layer SEM1 in the first direction DR1 and/or a length of of the bottom surface of the first semiconductor layer SEM1 in the second direction DR2 may be smaller than a length of the contact electrode CTE in the first direction DR1 and/or a length of the contact electrode CTE in the second direction DR2. The first semiconductor layer SEM1 may be formed of a semiconductor material layer doped with a first conductive dopant such as magnesium (Mg), zinc (Zn), calcium (Ca), strontium (Sr), barium (Ba), and/or the like, for example gallium nitride (GaN).

The active layer MQW may be arranged on the first semiconductor layer SEM1. The active material layer MQWL may include the same semiconductor material layer as the first semiconductor material layer SEML1 and the second semiconductor material layer SEML2. For example, if (e.g., when) the first semiconductor material layer SEML1 and the second semiconductor material layer SEML2 include gallium nitride (GaN), the active material layer MQWL may also include gallium nitride (GaN). For example, the active material layer MQWL may include at least one selected from among gallium nitride (GaN), indium gallium nitride (InGaN), and aluminum gallium nitride (AlGaN). The active layer MQW may be to emit light by the combination of electron-hole pairs in response to an electric signal applied through the first semiconductor layer SEM1 and the second semiconductor layer SEM2.

The active layer MQW may include a material having a single or multi-quantum well structure. When the active layer MQW includes a material having a multi-quantum well structure, it may have a structure in which a plurality of well layers and barrier layers are alternately stacked. In some embodiments, the well layer may be formed of indium gallium nitride (InGaN), and the barrier layer may be formed of gallium nitride (GaN) and/or aluminum gallium nitride (AlGaN), but embodiments of the present disclosure are not limited thereto. In one or more embodiments, the active layer MQW may have a structure in which semiconductor materials having a suitably high band gap energy and semiconductor materials having a suitably low band gap energy are alternately stacked with each other, may include other Group three to five (Group III-Group V) semiconductor materials according to the wavelength range of emitted light.

When the active layer MQW includes InGaN, the color of the emitted light may vary depending on the content (e.g., amount) of indium (In). For example, as the content (e.g., amount) of indium (In) increases, the wavelength band of light emitted by the active layer may shift to the red wavelength band, and as the content (e.g., amount) of indium (In) decreases, the wavelength band of light emitted by the active layer may shift to the blue wavelength band. For example, the content (e.g., amount) of indium (In) in the active layer MQW of the light emitting element LE that is to emit the third light (light in the blue wavelength band) may be approximately 10 wt % to 20 wt %.

The second semiconductor layer SEM2 may be arranged on the active layer MQW. The second semiconductor layer SEM2 may be a semiconductor material layer doped with a second conductive dopant, such as silicon (Si), germanium (Ge), tin (Sn), and/or the like, for example may be formed of gallium nitride (GaN).

An electron blocking layer may be arranged between the first semiconductor layer SEM1 and the active layer MQW. The electron blocking layer may be a layer for suppressing, preventing, or reducing too many electrons from flowing into the active layer MQW. For example, the electron blocking layer may be AlGaN or p-AlGaN doped with p-type Mg. In some embodiments, the electron blocking layer may not be provided.

A superlattice layer may be arranged between the active layer MQW and the second semiconductor layer SEM2. The superlattice layer may be a layer for relieving stress between the second semiconductor layer SEM2 and the active layer MQW. For example, the superlattice layer may be formed of InGaN and/or GaN. In some embodiments, the superlattice layer may not be provided.

The first protective layer INS1 may be arranged on the side of the first conductive layer E1, the side of the first semiconductor layer SEM1, the side of the active layer MQW, and the side of the second semiconductor layer SEM2. The first protective layer INS1 may be a film made of an insulating material for protecting the side of the light emitting element LE. The first protective layer INS1 may be formed of an inorganic film, such as silicon nitride (SiNₓ, for example, Si₃N₄), silicon oxynitride (SiOₓN_{y}), silicon oxide (SiOₓ, for example, SiO₂), titanium oxide (TiOₓ, for example, TiO₂), and/or aluminum oxide (AlOₓ, for example, Al₂O₃).

In some embodiments, the first protective layer INS1 may expose at least a portion of the side of the second semiconductor layer SEM2. For example, it may be arranged spaced apart from the top portion of the light emitting element LE.

In some embodiments, the first protective layer INS1 may be arranged only on the side of the first conductive layer E1, the side of the first semiconductor layer SEM1, the side of the active layer MQW, and the side of the second semiconductor layer SEM2, and may not be arranged on at least one other side of the first conductive layer E1.

In one or more embodiments, the first protective layer INS1 may be arranged not only on the side of the first conductive layer E1, the side of the first semiconductor layer SEM1, the side of the active layer MQW, and the side of the second semiconductor layer SEM2, but also on a portion of the first conductive layer E1. For example, the first protective layer INS1 may be arranged on a lower side of the first conductive layer E1. However, the first protective layer INS1 may expose at least a portion of the first conductive layer E1 (e.g., may expose at least a portion of the lower side of the first conductive layer E1).

The contact electrode CTE may be arranged on the first protective layer INS1. The contact electrode CTE may be arranged between the first organic layer 210 and the first protective layer INS1. The contact electrode CTE may be in contact with the first organic layer 210.

While FIGS. 6 and 7 illustrate that the contact electrodes CTE of each of the light emitting elements LE are arranged on the first organic layer 210, embodiments of the present disclosure are not limited thereto. For example, the first organic layer 210 may be arranged on the bottom surface and a portion of the side surface of the contact electrode CTE of each of the light emitting elements LE. In one or more other embodiments, the first organic layer 210 may be arranged on the side surface of the conductive layer E1 of each of the light emitting elements LE. In one or more other embodiments, the first organic layer 210 may be arranged on the side surface of the first semiconductor layer SEM1, the side surface of the active layer MQW, and the side surface of the second semiconductor layer SEM2 of each of the light emitting elements LE. In this case, the first organic layer 210 may be arranged on a portion of the side surface of the second semiconductor layer SEM2.

The contact electrode CTE may be connected to the exposed conductive layer E1 without being covered by the first protective layer INS1.

When the contact electrode CTE is formed of a metal having suitably high reflectivity, light emitted from the active layer MQW of the light emitting element LE and traveling in the lateral direction (e.g., sideways) of the light emitting element LE may be reflected by the contact electrode CTE and emitted to the top surface of the light emitting element LE. Therefore, because the loss of light from the light emitting element LE may be reduced, the light efficiency of the light emitting element LE may be increased. Therefore, when the contact electrode CTE is arranged to cover most of (or a suitable portion of) the lateral (e.g., side) surface of the semiconductor stack STC, the light efficiency of the light emitting element LE may be increased.

The contact electrode CTE may be arranged on the lateral surface of the semiconductor stack STC. An area adjacent to the top surface of the semiconductor stack STC on the lateral surface of the semiconductor stack STC may be covered by the protective layer INS, but may not be covered by a plurality of contact electrodes CTE. For example, the contact electrode CTE may be arranged spaced apart from the top surface of the semiconductor stack STC in the third direction DR3. Here, the third direction DR3 may be substantially the same as the height direction (or thickness direction) of the light emitting element LE. When the contact electrode CTE is spaced apart from the top surface of the semiconductor stack STC, the peeling off of the contact electrode CTE exposed to (e.g., positioned at or near) the top surface of the semiconductor stack STC by a chemical solution and/or the like during the manufacturing process may be prevented or reduced.

The contact electrode CTE may include one selected from among molybdenum (Mo), aluminum (AI), chromium (Cr), gold (Au), titanium (Ti), nickel (Ni), neodymium (Nd), and copper (Cu). For example, the contact electrode CTE may be formed from a two-layer structure of chromium (Cr) and gold (Au), a three-layer structure of titanium (Ti), aluminum (AI), and titanium (Ti), and/or a three-layer structure of indium tin oxide (ITO), silver (Ag), and indium tin oxide (ITO) to increase reflectivity.

However, the reflectivity of aluminum (Al) may be about twice as high as that of chromium (Cr), silver (Ag), and/or gold (Au). Therefore, in one or more embodiments of the present disclosure, the contact electrode CTE adopts (e.g., includes) aluminum (Al) with suitably high reflectivity. When aluminum (Al), which is relatively inexpensive, is adopted instead of gold (Au) as the contact electrode CTE, the manufacturing cost of the light emitting element LE may be reduced.

The second protective layer INS2 serves to protect the contact electrode CTE as a conductive material. For example, the second protective layer INS2 may prevent or reduce peeling by a chemical solution during the process. This will be described in more detail in the process method described later.

The second protective layer INS2 may be arranged on the side and one side (e.g., both lateral sides and a bottom or lower side) of the light emitting element LE on the contact electrode CTE. The second protective layer INS2 may not be arranged in an area adjacent to the top surface of the semiconductor stack STC on the side (e.g., one or both lateral sides) of the light emitting element LE. For example, it may be arranged spaced apart from the top surface of the light emitting element LE in the third direction DR3. Here, the third direction DR3 may be substantially the same as the height direction (or thickness direction) of the light emitting element LE.

The second protective layer INS2 may be a conductive light-transmitting material and is a material that may be sputtered and/or wet-etched with the same material as a connection electrode BE. The second protective layer INS2 may be formed with the same material as the connection electrode BE but the present disclosure is not limited thereto. For example, the second protective layer INS2 may be Indium Zinc Oxide (IZO).

Because the first protective layer INS1 is insulating and the second protective layer INS2 is conductive, the first protective layer INS1 may be referred to as an insulating protective layer, and the second protective layer INS2 may be referred to as a conductive protective layer or a conductive electrode protective layer.

The connection electrode BE connects the contact electrode CTE of the light emitting element LE and one of the pixel electrodes PXE1, PXE2, and PXE3. The connection electrode BE may be arranged on a portion of the side surface of the light emitting element LE, and may be arranged on the pixel electrode PXE1, PXE2, and PXE3 along the top surface and the side surface of the first organic layer 210. In FIG. 7, the connection electrode BE is arranged on the top portion of the pixel electrodes PXE1, PXE2, and PXE3 and is not arranged on the side portion of the pixel electrodes PXE1, PXE2, and PXE3 but the present disclosure is not limited thereto. For example, the connection electrode BE may be arranged on a portion of the side of the light emitting element LE, so that it is arranged on the top side and the side of the first organic layer 210 as well as on the top side of the pixel electrode PXE1, PXE2, and PXE3. For example, the connection electrode BE may be arranged on the top side and the side of the pixel electrode PXE1, PXE2, and PXE3 along the top side and the side of the first organic layer 210. Furthermore, the connection electrode BE may be arranged on a portion of the side surface of the light emitting element LE and may be arranged on the top surface and side surface of the first organic layer 210, on the top surface and side surface of the pixel electrode PXE1, PXE2, and PXE3, and/or on a portion of the second planarization organic film 180.

The connection electrode BE may not be in direct contact with the contact electrode CTE but may be electrically connected through the second protective layer INS2.

The connection electrode BE may be a material that may be sputtered and/or wet-etched with the same material as the connection electrode BE. For example, the connection electrode BE may be made of a transparent conductive material (TCO) such as indium tin oxide (ITO) and/or indium zinc oxide (IZO).

In one or more embodiments, the connection electrode BE may be made of the same IZO (Indium Zinc Oxide) as the second protective layer INS2.

A second organic layer 211 may be arranged to cover a lateral portion of the plurality of light emitting elements LE. Further, the second organic layer 211 may be arranged to cover the connection electrode BE, but a portion of the connection electrode BE may be exposed without being covered by the second organic layer 211.

The third organic layer 212 may be arranged on the second organic layer 211. The third organic layer 212 may be arranged to cover a portion of the side surface of each of the plurality of light emitting elements LE. The third organic layer 212 may be arranged on at least a portion of the connection electrode BE that is exposed (without being covered) by the second organic layer 211. The top surface of each of the plurality of light emitting elements LE may be exposed without being covered by the third organic layer 212.

The second organic layer 211 and the third organic layer 212 may be formed of an organic film, such as an acrylic resin, an epoxy resin, a phenolic resin, a polyamide resin, a polyimide resin, and/or the like.

The second organic layer 211 and the third organic layer 212 are layers for flattening (e.g., planarizing) the steps caused by the plurality of light emitting elements LE. When the height of the second organic layer 211 is arranged or selected to cover most of the side surfaces of each of the plurality of light emitting elements LE, the third organic layer 212 may not be provided.

The common electrode CE may be arranged on the top surface of each of the plurality of light emitting elements LE and the top surface of the third organic layer 212. The common electrode CE may be a common layer formed commonly on the first sub-pixel SPX1, the second sub-pixel SPX2, and the third sub-pixel SPX3. The common electrode CE may be made of a transparent conductive material (TCO), such as indium tin oxide (ITO) and/or indium zinc oxide (IZO), which may transmit light.

In one or more embodiments, the common electrode CE is not in contact with the connection electrode BE, the second protective layer INS2, and/or the contact electrode CTE.

As used herein, the pixel electrodes PXE1, PXE2, and PXE3 may be referred to as an anode electrode or a first electrode, and the common electrode CE may be referred to as a cathode electrode or a second electrode.

The first capping layer CAP1 may be arranged on the common electrode CE.

A light blocking layer BM, a first light conversion layer QDL1, a second light conversion layer QDL2, and a light transmission layer TPL may be arranged on the first capping layer CAP1. The first light conversion layer QDL1, the second light conversion layer QDL2, and the light transmission layer TPL may be formed (e.g., defined) by the compartments of the light blocking layer BM. Therefore, the first light conversion layer QDL1 may be arranged on the first capping layer CAP1 in the first sub-pixel SPX1, the second light conversion layer QDL2 may be arranged on the first capping layer CAP1 in the second sub-pixel SPX2, and the light transmission layer TPL may be arranged on the first capping layer CAP1 in the third sub-pixel SPX3. The light blocking layer BM overlaps the second organic layer 211 and the third organic layer 212 in the third direction DR3 and may not overlap the plurality of light emitting elements LE.

The first light conversion layer QDL1 may convert a portion of the third light (light in the blue wavelength band) incident from the light emitting element LE into first light (light in the red wavelength band). The first light conversion layer QDL1 may include a first base resin BRS1 and a first wavelength conversion particle WCP1. The first base resin BRS1 may include a light-transmitting organic material. The first wavelength conversion particle WCP1 may convert a portion of the third light (light in the blue wavelength band) incident from the light emitting element LE into first light (light in the red wavelength band).

The second light conversion layer QDL2 may convert a portion of the third light (light in the blue wavelength band) incident from the light emitting element LE into second light (light in the green wavelength band). The second light conversion layer QDL2 may include a second base resin BRS2 and a second wavelength conversion particle WCP2. The second base resin BRS2 may include a light-transmitting organic material. The second wavelength conversion particle WCP2 may convert a portion of the third light (light in the blue wavelength band) incident from the light emitting element LE into second light (light in the green wavelength band).

The light transmission layer TPL may include a light-transmitting organic material.

For example, the first base resin BRS1, the second base resin BRS2, and the light transmission layer TPL may include an epoxy-based resin, an acrylic-based resin, a cardo-based resin, and/or an imide-based resin. The first and second wavelength conversion particles WCP1 and WCP2 may be quantum dots (QD), quantum rods, fluorescent materials, and/or phosphorescent materials.

The light blocking layer BM may include a first light blocking layer BM1 and a second light blocking layer BM2 that are sequentially stacked. A length of the first light blocking layer BM1 in the first direction DR1 and/or a length of the first light blocking layer BM1 in the second direction DR2 may be wider (e.g., larger) than a length of the second light blocking layer BM2 in the first direction DR1 and/or a length of the second light blocking layer BM2 in the second direction DR2. The first light blocking layer BM1 and the second light blocking layer BM2 may be formed of an organic film such as an acrylic resin, an epoxy resin, a phenolic resin, a polyamide resin, a polyimide resin, and/or the like. The first light blocking layer BM1 and the second light blocking layer BM2 may include a light blocking material to prevent or reduce the possibility of light from the light emitting element LE of one sub-pixel proceeding to the neighboring sub-pixel. For example, the first light blocking layer BM1 and the second light blocking layer BM2 may include an inorganic black pigment such as carbon black and/or an organic black pigment.

The second capping layer CAP2 may be arranged on the first capping layer CAP1 and the light blocking layer BM. The second capping layer CAP2 may be arranged on the side and top surfaces of the light blocking layer BM. For example, the second capping layer CAP2 may be arranged on the side of the first light blocking layer BM1 and the side and top surfaces of the second light blocking layer BM2.

The reflective film RF may be arranged between the light blocking layer BM and the first light conversion layer QDL1, between the light blocking layer BM and the second light conversion layer QDL2, and between the light blocking layer BM and the light transmission layer TPL. The reflective film RF may be arranged on the second capping layer CAP2 arranged on the side of the first light blocking layer BM1 and the side of the second light blocking layer BM2. The reflective film RF serves to reflect light traveling in the lateral direction from the first light conversion layer QDL1, the second light conversion layer QDL2, and/or the light transmission layer TPL.

The reflective film RF may include a highly or suitably reflective metal material such as aluminum (Al). The thickness of the reflective film RF may be approximately 0.1 μm.

In one or more embodiments, the reflective film RF may include a first layer and a second layer of M (where M is an integer of 2 or more) pairs having different refractive indices to serve as Distributed Bragg Reflectors (DBR). In this case, M first layers and M second layers may be arranged alternately. The first layer and the second layer may be formed of an inorganic film, for example, silicon nitride (SiNₓ, for example, Si₃N₄), silicon oxynitride (SiOₓN_{y}), silicon oxide (SiOₓ, for example, SiO₂), titanium oxide (TiOₓ, for example, TiO₂), and/or aluminum oxide (AlOₓ, for example, Al₂O₃).

The third capping layer CAP3 may be arranged on the second capping layer CAP2, the first light conversion layer QDL1, the second light conversion layer QDL2, and the light transmission layer TPL.

The first capping layer CAP1, the second capping layer CAP2, and the third capping layer CAP3 may be formed of an inorganic film, for example, silicon nitride (SiNₓ, for example, Si₃N₄), silicon oxynitride (SiOₓN_{y}), silicon oxide (SiOₓ, for example, SiO₂), titanium oxide (TiOₓ, for example, TiO₂), and/or aluminum oxide (AlOₓ, for example, Al₂O₃). The first light conversion layer QDL1, the second light conversion layer QDL2, and the light transmission layer TPL may be encapsulated by the first capping layer CAP1, the second capping layer CAP2, and the third capping layer CAP3.

A fourth organic layer 213 may be arranged on the third capping layer CAP3. A plurality of color filters CF1, CF2, and CF3 may be arranged on the fourth organic layer 213. The plurality of color filters CF1, CF2, and CF3 may include first color filters CF1, second color filters CF2, and third color filters CF3.

The first color filter CF1 arranged in the first sub-pixel SPX1 may be to transmit the first light (light in the red wavelength band) and absorb or block or reduce the third light (light in the blue wavelength band). Therefore, the first color filter CF1 may be to transmit the first light (light in the red wavelength band) that has been converted by the first light conversion layer QDL1 among the third light (light in the blue wavelength band) emitted from the light emitting element LE and absorb or block or reduce the third light (light in the blue wavelength band) that has not been converted by the first light conversion layer QDL1. Accordingly, the first sub-pixel SPX1 may be to emit the first light (light in the red wavelength band).

The second color filter CF2 arranged in the second sub-pixel SPX2 may be to transmit the second light (light in the green wavelength band) and absorb or block or reduce the third light (light in the blue wavelength band). Therefore, the second color filter CF2 may be to transmit the second light (light in the green wavelength band) that has been converted by the second light conversion layer QDL2 among the third light (light in the blue wavelength band) emitted from the light emitting element LE and absorb or block or reduce the third light (light in the blue wavelength band) that has not been converted by the second light conversion layer QDL2. Accordingly, the second sub-pixel SPX2 may be to emit the second light (light in the green wavelength band).

The third color filter CF3 arranged in the third sub-pixel SPX3 may be to transmit the third light (light in the blue wavelength band). Therefore, the third color filter CF3 may be to transmit the third light (light in the blue wavelength band) emitted from the light emitting element LE passing through the light transmission layer TPL. Accordingly, the third sub-pixel SPX3 may be to emit the third light (light in the blue wavelength band).

The first color filter CF1, the second color filter CF2, and the third color filter CF3 overlapping in the third direction DR3 may overlap with the light blocking layer BM in the third direction DR3.

A fifth organic layer 214 for planarization may be arranged on the plurality of color filters CF1, CF2, and CF3.

The fourth organic layer 213 and the fifth organic layer 214 may be formed from an acrylic resin, an epoxy resin, a phenolic resin, a polyamide resin, a polyimide resin, and/or the like.

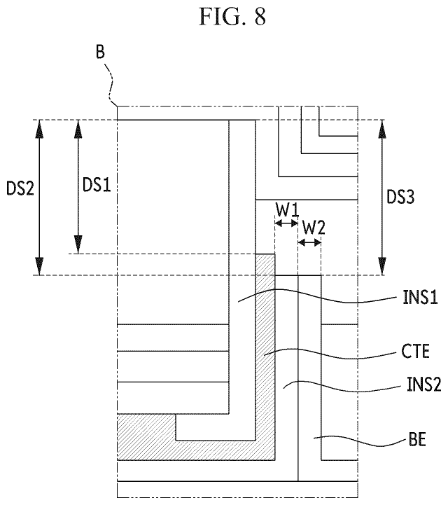

FIG. 8 is a cross-sectional view illustrating an example of area B of FIG. 7 in more detail.

Referring to FIG. 8, a first protective layer INS1 may be on (e.g., may surround) a side surface of the semiconductor stack STC. The contact electrode CTE may be on the first protective layer INS1 and may be around (e.g., may surround) a portion of the side surface of the semiconductor stack STC. An area adjacent to the top surface of the semiconductor stack STC on the side surface of the semiconductor stack STC may be covered by the protective layer INS1 but may be exposed without being covered by a plurality of contact electrodes CTE.

The second protective layer INS2 and the connection electrode BE may be on (e.g., may surround) a portion of the side surface of the light emitting element LE.

The second protective layer INS2 may be arranged closer to the light emitting element LE than the connection electrode BE. For example, the second protective layer INS2 may be in contact with the contact electrode CTE, and the connection electrode BE may be in contact with the second protective layer INS2. Because the second protective layer INS2 is a conductive passivation layer, it electrically connects the contact electrode CTE and the connection electrode BE.

On the side of the light emitting element LE, an area adjacent to the top surface of the light emitting element LE may be exposed without being covered by the second protective layer INS2 and the connection electrode BE.

In the third direction DR3, the height of the second protective layer INS2 and the connection electrode BE may be lower than that of the contact electrode CTE. For example, in the third direction DR3, the distance DS1 between the top surface of the light emitting element LE (or the top surface of the semiconductor stack STC) and the contact electrode CTE is smaller (e.g., closer) than the distance DS2 between the top surface of the light emitting element LE and the second protective layer INS2, and smaller (e.g., closer) than the distance DS3 between the top surface of the light emitting element LE and the connection electrode BE. In some embodiments, the distance DS2 between the top surface of the light emitting element LE and the second protective layer INS2 is the same as the distance DS3 between the top surface of the light emitting element LE and the connection electrode BE. The third direction DR3 may be the thickness direction of the light emitting element LE and a stacking direction of the semiconductor layer.

The thickness W1 of the second protective layer INS2 and the thickness W2 of each of the connection electrodes BE may be the same. The thickness W1 of the second protective layer INS2 and the thickness W2 of each of the connection electrodes BE are the widths in the outward direction from the side surface of the light emitting element LE (e.g., in the first direction DR1).

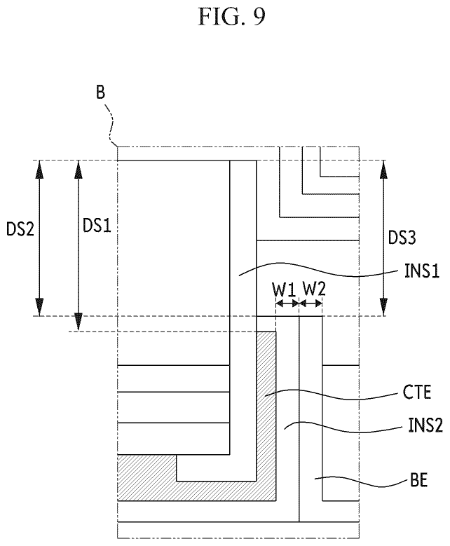

FIG. 9 is a cross-sectional view illustrating another example of area B of FIG. 7 in more detail.

Referring to FIG. 9, the height of the second protective layer INS2 and that of the connection electrode BE differ from the embodiment of FIG. 8 in that the second protective layer INS2 is formed higher than the contact electrode CTE, and the upper portion of the second protective layer INS2 may be above (e.g., may surround) the contact electrode CTE.

On the side of the light emitting element LE, an area adjacent to the top surface of the light emitting element LE may be exposed without being covered by the second protective layer INS2 and the connection electrode BE.

In the third direction DR3, the height of the second protective layer INS2 and the connection electrode BE may be higher (or larger) than that of the contact electrode CTE. For example, in the third direction DR3, the distance DS1 between the top surface of the light emitting element LE (or the top surface of the semiconductor stack STC) and the contact electrode CTE is larger (e.g., further) than the distance DS2 between the top surface of the light emitting element LE and the second protective layer INS2, and larger (e.g., further) than the distance DS3 between the top surface of the light emitting element LE and the connection electrode BE. The distance DS2 between the top surface of the light emitting element LE and the second protective layer INS2 and the distance DS3 between the top surface of the light emitting element LE and the connection electrode BE may be the same. The third direction DR3 may be the thickness direction of the light emitting element LE and a stacking direction of the semiconductor layer.

The second protective layer INS2 may cover one end of the contact electrode CTE. For example, one end of the contact electrode CTE may be surrounded by the second protective layer INS2 and the first protective layer INS1 and may not be exposed.

The thickness W1 of the second protective layer INS2 and the thickness W2 of each connection electrode BE may be the same. The thickness W1 of the second protective layer INS2 and the thickness W2 of each connection electrode BE are the widths in the outward direction (e.g., in the first direction DR1) from the side surface of the light emitting element LE.

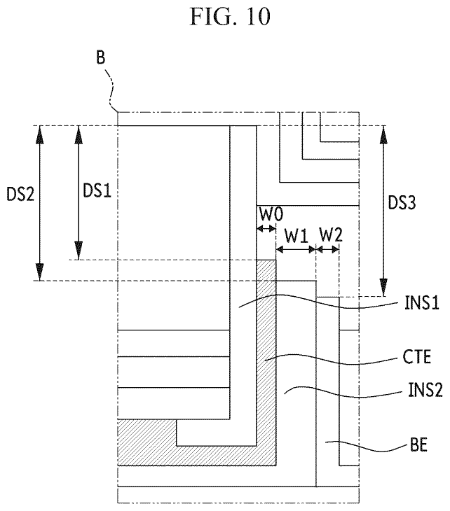

FIG. 10 is a cross-sectional view illustrating another example of area B of FIG. 7 in more detail.

Referring to FIG. 10, the embodiment is different from that of FIG. 8 in that the height of the connection electrode BE is lower than the height of the second protective layer INS2.

Referring to FIG. 10, the side of the semiconductor stack STC may be covered (e.g., surrounded) by the first protective layer INS1. The contact electrode

CTE may cover (e.g., surround) a portion of the side of the semiconductor stack STC on the first protective layer INS1. An area adjacent to the top surface of the semiconductor stack STC on the side of the semiconductor stack STC may be covered by the protective layer INS but may be exposed without being covered by a plurality of contact electrodes CTE.

The second protective layer INS2 and the connection electrode BE may cover (e.g., may surround) a portion of the side of the light emitting element LE. The second protective layer INS2 may be arranged closer to the light emitting element LE than the connection electrode BE. For example, the second protective layer INS2 may be in contact with the contact electrode CTE, and the connection electrode BE may be in contact with the second protective layer INS2. The second protective layer INS2 is a conductive protective layer, so it electrically connects the contact electrode CTE and the connection electrode BE.

An area adjacent to the top surface of the light emitting element LE from the side of the light emitting element LE may be exposed without being covered by the second protective layer INS2 and the connection electrode BE.

In the third direction DR3, the height of the second protective layer INS2 and that of the connection electrode BE may be lower than that of the contact electrode CTE. For example, in the third direction DR3, the distance DS1 between the top surface of the light emitting element LE (or the top surface of the semiconductor stack STC) and the contact electrode CTE may be smaller (e.g., closer) than the distance DS2 between the top surface of the light emitting element LE and the second protective layer INS2, and smaller (e.g., closer) than the distance DS3 between the top surface of the light emitting element LE and the connection electrode BE.

Furthermore, the distance DS2 between the top surface of the light emitting element LE and the second protective layer INS2 is smaller (e.g., closer) than the distance DS3 between the top surface of the light emitting element LE and the connection electrode BE. The third direction DR3 may be the thickness direction of the light emitting element LE and a stacking direction of the semiconductor layer.

The thickness W1 of the second protective layer INS2 may be thicker than the thickness W2 of the connection electrode BE. Also, the thickness W1 of the second protective layer INS2 may be thicker than the thickness WO of the contact electrode CTE.

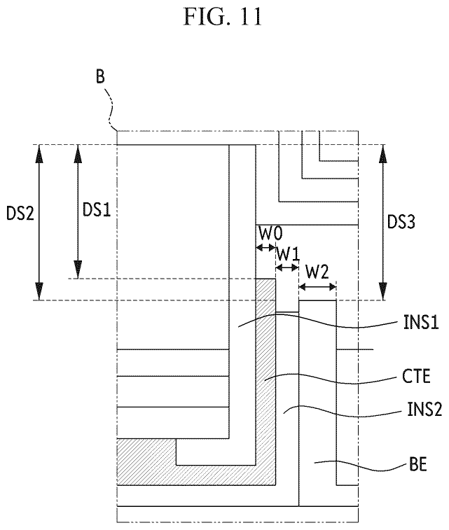

FIG. 11 is a cross-sectional view illustrating another example of area B of FIG. 7 in more detail.

Referring to FIG. 11, the embodiment is different from that of FIG. 8 in that the height of the connection electrode BE is higher than the height of the second protective layer INS2.

Referring to FIG. 11, the side surface of the semiconductor stack STC may be covered (e.g., surrounded) by the first protective layer INS1. The contact electrode CTE may cover (e.g., surround) a portion of the side surface of the semiconductor stack STC on the first protective layer INS1. Among the side surfaces of the semiconductor stack STC, an area adjacent to the top surface of the semiconductor stack STC may be covered by the protective layer INS but may be exposed without being covered by a plurality of contact electrodes CTE.

The second protective layer INS2 and the connection electrode BE may cover (e.g., surround) a portion of the side surface of the light emitting element LE. The second protective layer INS2 may be arranged closer to the light emitting element LE than the connection electrode BE. For example, the second protective layer INS2 may be in contact with the contact electrode CTE, and the connection electrode BE may be in contact with the second protective layer INS2. The second protective layer INS2 is a conductive protective layer, so it electrically connects the contact electrode CTE and the connection electrode BE.

On the side of the light emitting element LE, an area adjacent to the top surface of the light emitting element LE may be exposed without being covered by the second protective layer INS2 and the connection electrode BE.

In the third direction DR3, the height of the second protective layer INS2 and that of the connection electrode BE may be lower than the height of the contact electrode CTE. For example, in the third direction DR3, the distance DS1 between the top surface of the light emitting element LE (or the top surface of the semiconductor stack STC) and the contact electrode CTE is smaller (e.g., closer) than the distance DS2 between the top surface of the light emitting element LE and the second protective layer INS2, and smaller (e.g., closer) than the distance DS3 between the top surface of the light emitting element LE and the connection electrode BE. The distance DS2 between the top surface of the light emitting element LE and the second protective layer INS2 may be longer (e.g., further) than the distance DS3 between the top surface of the light emitting element LE and the connection electrode BE. The third direction DR3 may be the thickness direction of the light emitting element LE and a stacking direction of the semiconductor layer.

The thickness W2 of the connection electrode BE may be thicker than the thickness W1 of the second protective layer INS2. The thickness W2 of the connection electrode BE may be thicker than the thickness WO of the contact electrode.

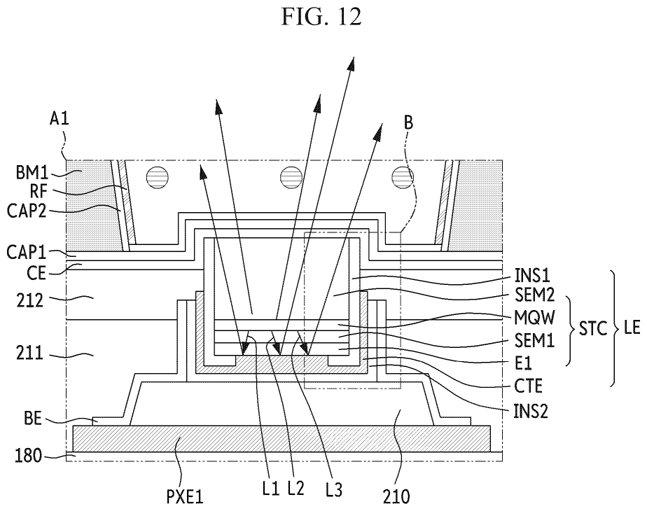

FIG. 12 is a schematic diagram illustrating light emitted from a light emitting element in one or more embodiments of FIG. 7.

Referring to FIG. 12, the light emitted from the active layer MQW of the light emitting element LE travels downward as well as upward. The light L1, L2, and L3 that travels in a downward direction is reflected by a contact electrode CTE including a metal with a suitably high reflectivity, for example, aluminum (Al), and then travels in an upward direction. By way of contrast, if (e.g., when) the contact electrode CTE is formed of a metal with a relatively low (e.g., unsuitable) reflectivity, for example, chromium (Cr) and/or gold (Au), the reflectivity of light emitted in the downward direction from the light emitting element LE may be reduced, which may lower the light emitting efficiency of the display device.

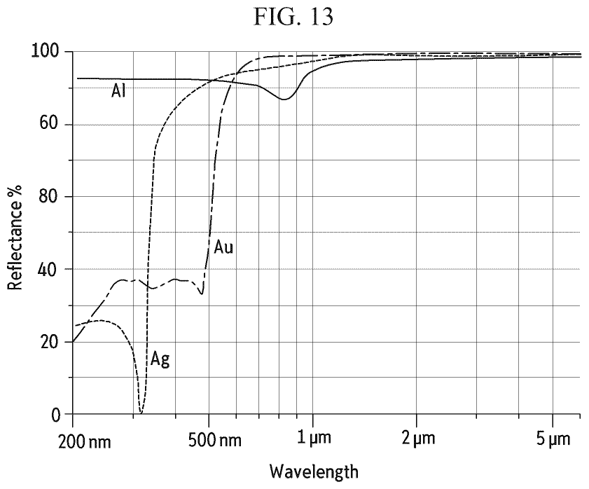

FIG. 13 is a graph illustrating reflectivity for wavelengths of aluminum, chromium, and gold.

Referring to FIG. 13, the reflectivity of aluminum (Al) is about 92% or higher at most wavelengths. By way of comparison, gold (Au) has a reflectivity of less than 38% for wavelengths from 200 nm to 500 nm, and silver (Ag) has a reflectivity of less than 25% for wavelengths from 200 nm to 350 nm. Therefore, if (e.g., when) the contact electrode (CTE of FIG. 12) adopts (e.g., includes) aluminum (Al), the reflectivity of light emitted in a downward direction may be improved by about 2.5 to 3 times. For example, if (e.g., when) the contact electrode (CTE of FIG. 12) adopts aluminum (Al), the brightness of the display device may be increased by contributing to the light extraction of the light emitting element LE.

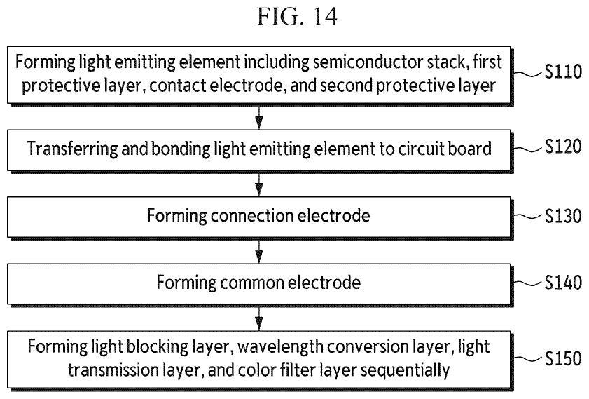

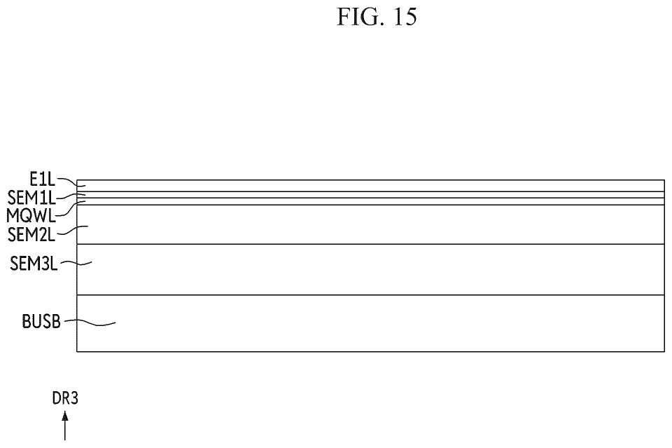

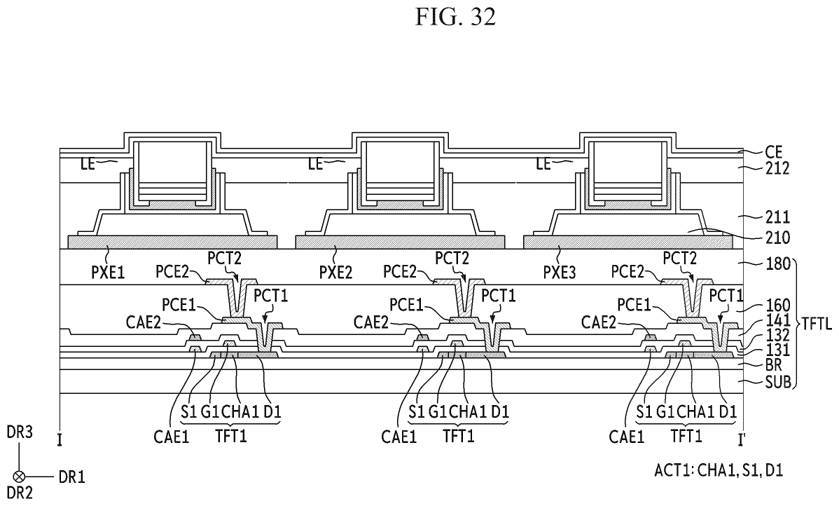

FIG. 14 is a flow chart illustrating a method for manufacturing a display device according to one or more embodiments. FIGS. 15-33 are example diagrams to illustrate a method of manufacturing a display device according to one or more embodiments.

In the following, FIGS. 15-33 illustrate cross-sectional views of the structures according to the formation order of each layer of the display device. FIGS. 14-33 focus on the formation of a light emitting element LE and a light emitting element layer. Hereinafter, a method for manufacturing the display device illustrated in FIGS. 15-33 will be described in conjunction with FIG. 14.

First, in act S110 of FIG. 14, a light emitting element LE including a semiconductor stack STC, a first protective layer INS1, a contact electrode CTE, and a second protective layer INS2 is formed on a semiconductor substrate BSUB. (S110 of FIG. 14).

For example, referring to FIG. 15, a semiconductor substrate BSUB is prepared. The semiconductor substrate BSUB may be a sapphire substrate (Al₂O₃) and/or a transparent silicon wafer containing silicon. However, it is not limited thereto, and in one or more embodiments, a case in which the semiconductor substrate BSUB is a sapphire substrate is described as an example.

A plurality of semiconductor material layers SEM3L, SEM2L, MQWL, SEM1L, and EL1 are formed on a semiconductor substrate BSUB. The plurality of semiconductor material layers grown by the epitaxial method may be formed by growing a seed crystal. Methods for forming semiconductor material layers may include electron beam deposition, physical vapor deposition (PVD), chemical vapor deposition (CVD), and/or plasma laser deposition (PLD), dual-type or kind thermal evaporation, sputtering, metal organic chemical vapor deposition (MOCVD), and/or the like, and in some embodiments, the layers may be formed by metal organic chemical vapor deposition (MOCVD). However, the method is not limited thereto.

A precursor material for forming the plurality of semiconductor material layers is not particularly limited so long as the precursor material is suitable for forming the subject material. In some embodiments, the precursor material may be a metal precursor including an alkyl group such as a methyl and/or ethyl group. For example, it may be a compound such as trimethyl gallium (Ga(CH₃)₃), trimethyl aluminum (Al(CH₃)₃), triethyl phosphate ((C₂H₅)₃PO₄) but are not limited thereto.

For example, a third semiconductor material layer SEM3L is formed on the semiconductor substrate BSUB. In FIG. 15, the third semiconductor layer SEM3 is illustrated as being laminated in one layer but the present disclosure is not limited thereto, and a plurality of layers may be formed.

The third semiconductor material layer SEM3L may be arranged to reduce the lattice constant difference between the second semiconductor material layer SEM2L and the semiconductor substrate BSUB. In some embodiments, the third semiconductor material layer SEM3L may include an undoped semiconductor and may be a material that is not doped as n-type or p-type (e.g., is not doped with an n-type or p-type dopant). In one or more embodiments, the third semiconductor material layer SEM3L may be at least one selected from among undoped InAlGaN, GaN, AlGaN, InGaN, AlN, and InN but the present disclosure is not limited thereto.

The second semiconductor material layer SEM2L, the active material layer MQWL, and the first semiconductor material layer SEM1L may be sequentially formed on the third semiconductor material layer SEM3L using any suitable method, for example, the above-described method. In some embodiments, a superlattice material layer may be formed between the second semiconductor material layer SEM2L and the active material layer MQWL. In some embodiments, an electron blocking material layer may be formed between the active material layer MQWL and the first semiconductor material layer SEM1L. A conductive material layer E1L may be further formed on the first semiconductor material layer SEM1L. The conductive material layer E1L may be made of a transparent conductive material (TCO) such as indium tin oxide (ITO) and/or indium zinc oxide (IZO) that is capable of transmitting light but the present disclosure is not limited thereto. In some embodiments, the conductive material layer E1L may not be provided.

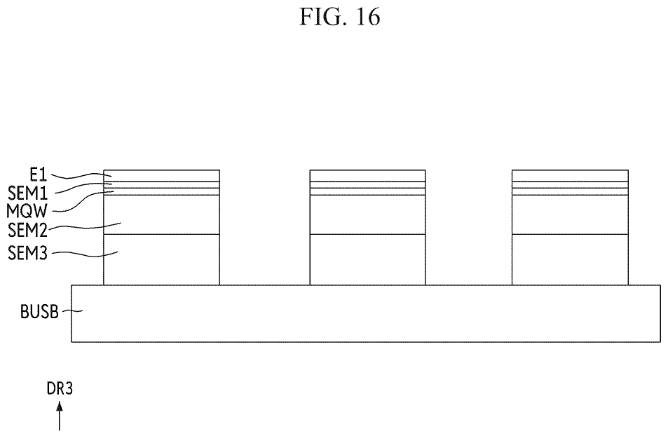

Referring to FIG. 16, after forming a mask pattern on the conductive material layer E1L, the third semiconductor material layer SEM3L, the second semiconductor material layer SEM2L, the active material layer MQWL, the first semiconductor material layer SEM1L, and the conductive material layer E1L are etched according to a first mask pattern to form semiconductor stacks. The first mask pattern may be removed after forming the semiconductor stacks (e.g., as a plurality of light emitting elements LE).

The etching process may be performed by dry etching, wet etching, reactive ion etching (RIE), deep reactive ion etching (DRIE), inductively coupled plasma reactive ion etching (ICP-RIE), and/or the like. In the case of a dry etching method, anisotropic etching is possible, so it may be suitable for vertical etching. When using a dry etching method, the etching gas may be Cl₂ and/or O₂ but the present disclosure is not limited thereto.

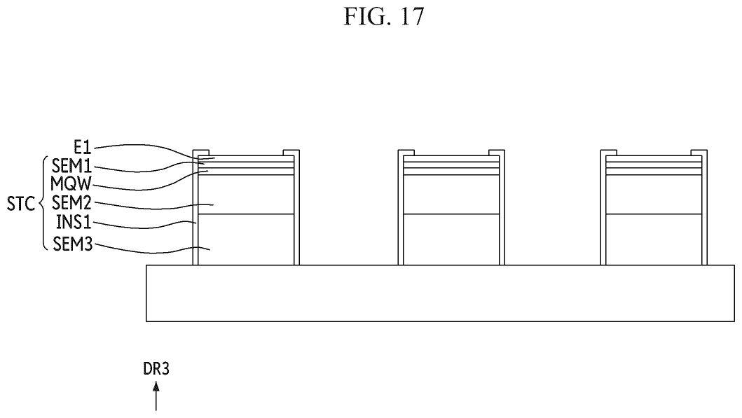

Then, referring to FIG. 17, a first protective layer INS1 covering side surfaces of the first semiconductor layer SEM1, the active layer MQW, the second semiconductor layer SEM2, and the third semiconductor layer SEM3 in each of the plurality of semiconductor stacks STC may be formed. In one or more embodiments, the third semiconductor layer SEM3 may be referred to as an undoped semiconductor layer. The first protective layer INS1 may cover a portion of the conductive layer E1 (e.g., a portion of a top surface of the conductive layer E1). In this case, the first protective layer INS1 may (e.g., should) expose at least a portion of the conductive layer E1 (e.g., another portion of the top surface of the conductive layer E1).

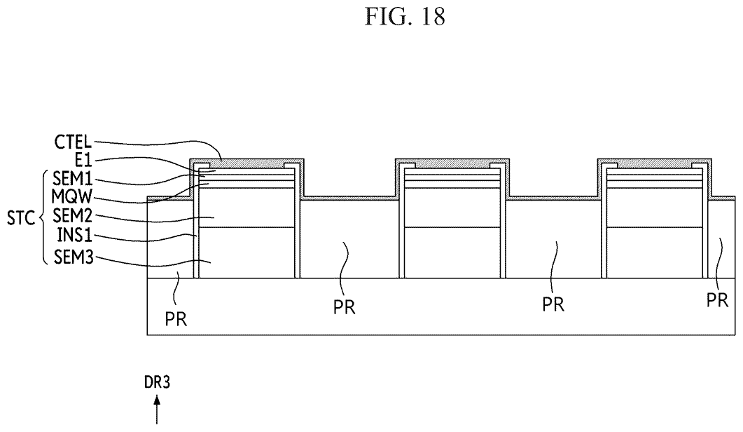

Referring to FIG. 18, a second mask pattern PR may be formed on a portion of one side of each of the semiconductor stacks STC and between the semiconductor stacks STC.

A contact electrode layer CTEL may be completely deposited on one side of the semiconductor substrate BSUB (e.g., may completely cover one side of the semiconductor substrate BSUB).

The contact electrode layer CTEL may be formed to cover one side (e.g., top surface) and side surfaces of the light emitting elements LE. The contact electrode layer CTEL may be arranged to cover the second mask pattern PR. The contact electrode layer CTEL may be formed on one side of the semiconductor substrate BSUB exposed between the light emitting elements LE (e.g., may be formed on the second mask pattern PR arranged between the light emitting elements LE).

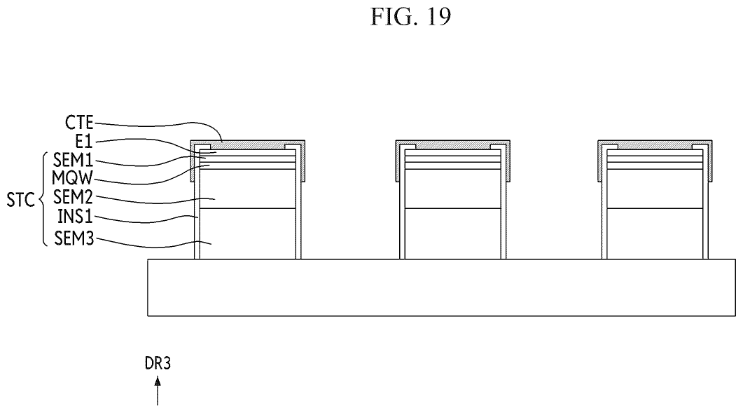

Referring to FIG. 19, the second mask pattern PR is removed, and the contact electrode CTE is formed. The contact electrode CTE may be formed to include aluminum (Al) having suitably high reflectivity.

For example, the second mask pattern PR may be removed by a lift-off process. To remove the second mask pattern PR by a lift-off process, the second mask pattern PR may be formed with a negative photoresist. For example, only the second mask pattern PR and the contact electrode layer CTEL arranged on the second mask pattern PR may be removed by a solvent ashing process using alcohol.

When the second mask pattern PR is removed, the contact electrode CTE may be exposed without covering (e.g., without fully covering) the first protective layer INS1 arranged on the side surface of the third semiconductor layer SEML3.

In one or more embodiments, if the thickness of the second mask pattern PR arranged between the light emitting elements LE is reduced, the area of the contact electrode CTE covering the first protective layer INS1 arranged on the side surface of the semiconductor stack STC may be increased. As a result, the light emitted from the active layer MQW of the light emitting element LE and traveling in the lateral direction of the light emitting element LE may be reflected and emitted to the top surface of the light emitting element LE due to the contact electrode CTE. Therefore, because the loss of light from the light emitting element LE may be reduced, the light efficiency of the light emitting element LE may be increased. The first protective layer INS1 may be formed of an insulating material, for example, silicon nitride (SiNₓ), silicon oxynitride (SiON), silicon oxide (SiOₓ), titanium oxide (TiOₓ), and/or aluminum oxide (AlOₓ).

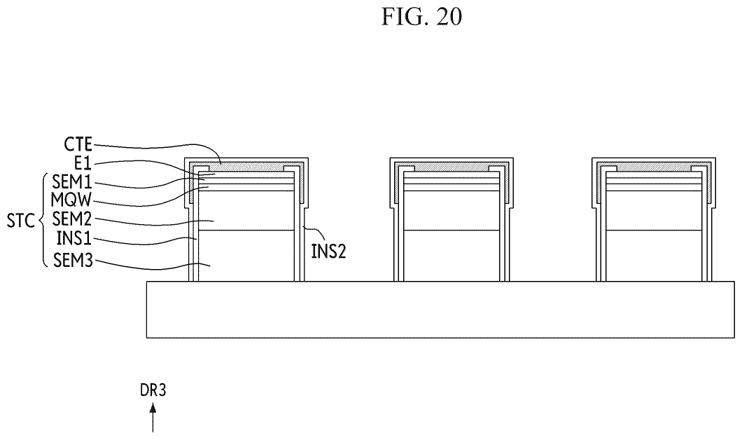

Then, referring to FIG. 20, a conductive second protective layer INS2 may be formed. The second protective layer INS2 may completely surround the contact electrode CTE (e.g., may cover the exposed surfaces of the contact electrode CTE). The second protective layer INS2 is a conductive material that does not react with the etchant described in more detail herein below. For example, the second protective layer INS2 may be formed of indium zinc oxide (IZO).

Thereby, the contact electrode CTE may be protected from exposure to the chemical solution used in the cleaning process described in more detail herein below.

The chemical solution may be tetramethylammonium hydroxide (TMAH), but the embodiment of the present disclosure is not limited thereto. When aluminum is exposed to tetramethylammonium hydroxide (TMAH), a peel-off phenomenon may occur in the contact electrode CTE including aluminum. In one or more embodiments, the second protective layer INS2 that does not react to the chemical solution (e.g., does not react with TMAH) is formed to completely surround the contact electrode CTE (e.g., cover the exposed surfaces of the contact electrode CTE), so that the contact electrode CTE may be formed to include aluminum having suitably high reflectivity without or substantially without damage by the chemical solution.

Second, in act S120 of FIG. 14, the light emitting element LE is transferred and bonded onto the substrate SUB. (S120 of FIG. 14)

The substrate SUB may be referred to as a circuit board SUB to clarify the distinction from the semiconductor substrate BSUB described above.

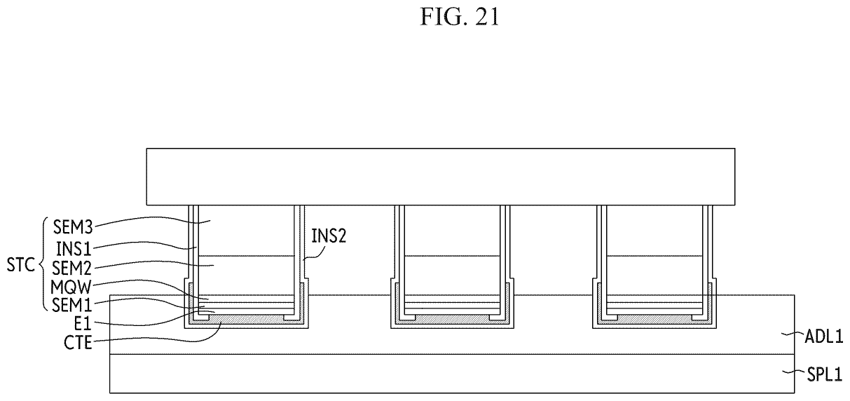

For example, referring to FIG. 21, a plurality of light emitting elements LE of the semiconductor substrate BSUB are moved to a first adhesive layer ADL1 arranged on a first relay substrate SPL1. The first relay substrate SPL1 may be made of a transparent material that allows light to pass through. For example, the first relay substrate SPL1 may include a transparent polymer such as polyimide, polyester, polyacrylic, polyepoxy, polyethylene, polystyrene, polyethylene terephthalate, and/or the like. The first adhesive layer ADL1 arranged on one surface of the first relay substrate SPL1 may include an adhesive material for adhering the plurality of light emitting elements LE. For example, the adhesive material may include urethane acrylate, epoxy acrylate, polyester acrylate, and/or the like.

The second protective layer INS2 of each of the plurality of light emitting elements LE may be adhered to the first adhesive layer ADL1 arranged on the first relay substrate SPL1.

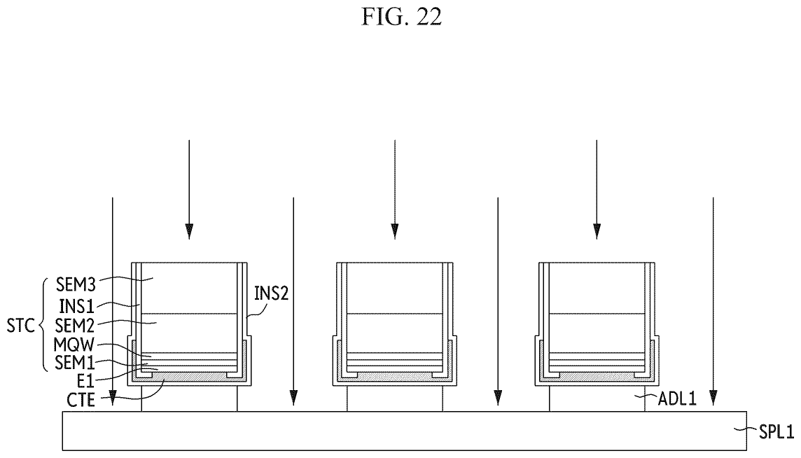

Then, referring to FIG. 22, the plurality of light emitting elements LE may be separated from the semiconductor substrate BSUB by a laser lift off (LLO) process of irradiating the semiconductor substrate BSUB with a laser.

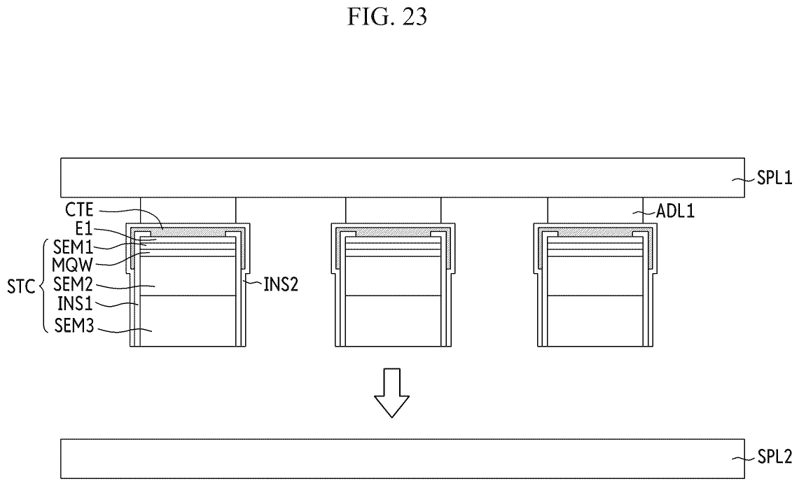

As shown in FIG. 23, the plurality of light emitting elements LE of the first relay substrate SPL1 are moved onto the first transfer substrate SPL2.

The first transfer substrate SPL2 may be made of a transparent material so that light may be transmitted. For example, the first transfer substrate SPL2 may include a transparent polymer such as polyimide, polyester, polyacrylic, polyepoxy, polyethylene, polystyrene, polyethylene terephthalate, and/or the like.

Each of a plurality of light emitting elements LE may be arranged on one side of the first transfer substrate SPL2. An adhesive layer having adhesiveness may also be further included on the first transfer substrate SPL2. For example, the adhesive layer is a layer that may be separated by laser irradiation, and may include, for example, a transparent polymer such as polyimide.

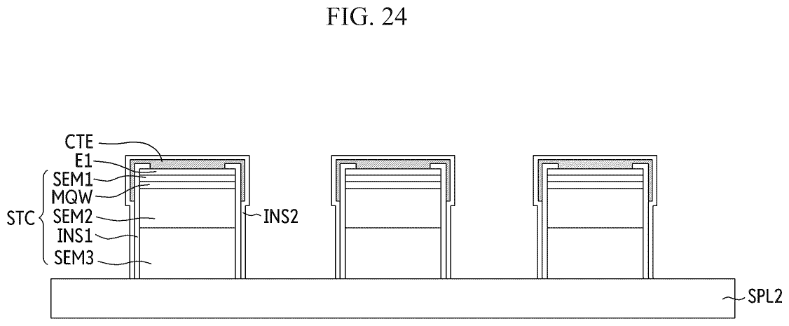

When heat is applied while bringing one surface of each of the plurality of light emitting elements LE into contact with the adhesive layer as shown in FIG. 24, each of the plurality of light emitting elements LE may be adhered or fixed to the adhesive layer, and if (e.g., when) the adhesive strength of the adhesive layer is weakened, each of the plurality of light emitting elements LE may be separated from the first adhesive layer ADL1. The one surface of each of the plurality of light emitting elements LE in contact with the adhesive layer on the first transfer substrate SPL2 may be opposite to the surface of each of the plurality of light emitting elements LE on which the second protective layer INS2 is arranged. Thereafter, the second transfer substrate SPL2 may be removed. After transferring the light emitting elements LE in this manner, a cleaning process may be performed. Contaminants including the adhesive layer on the light emitting elements LE may be removed by the cleaning process. As described above, the first transfer substrate SPL2 may be cleaned with a chemical solution. The chemical solution may be tetramethylammonium hydroxide (TMAH), but the embodiments of the present disclosure are not limited thereto. The contact electrode CTE may be a material that may be damaged by the chemical solution, but it may be protected from the chemical solution because it is surrounded (covered) by the second protective layer INS2 that does not react with the chemical solution.

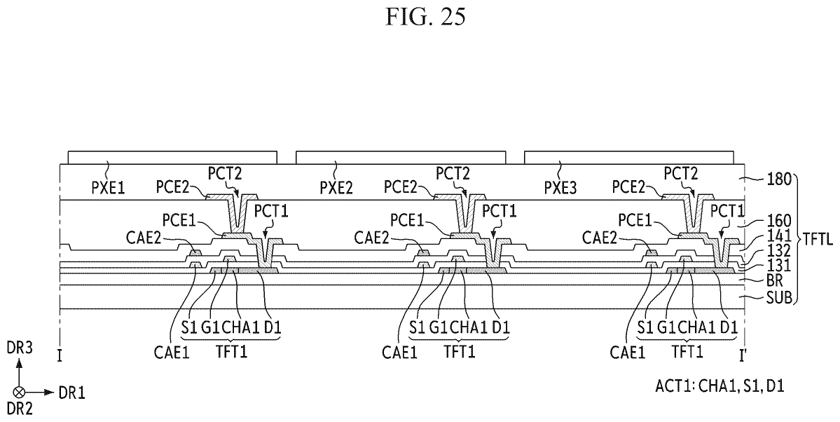

In one or more embodiments, as shown in FIG. 25, a circuit board SUB on which pixel electrodes PXE1, PXE2, and PXE3 are disposed is prepared. Here, the circuit board may be a circuit board SUB included in the transistor layer TFTL described with reference to FIG. 6.

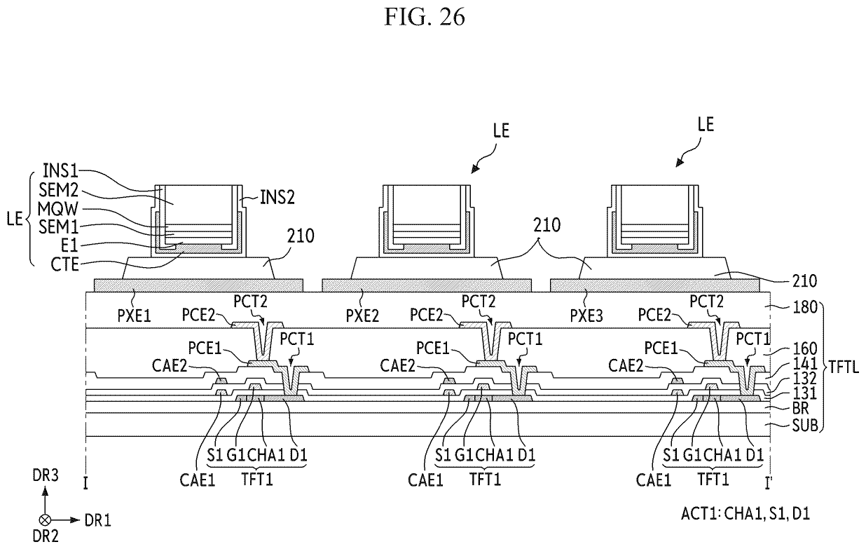

As shown in FIG. 26, a first organic layer 210 is formed on the pixel electrodes PXE1, PXE2, and PXE3. The light emitting elements LE may be moved onto the first organic layer 210. At this time, the light emitting elements LE may be temporarily fixed by being embedded in the first organic layer 210. For example, the second protective layer INS2 is exemplified as being arranged on the first organic layer 210, but the embodiment of the present disclosure is not limited thereto. For example, the first organic layer 210 may be arranged on a portion of the bottom surface and side surface of the second protective layer INS2 of each of the light emitting elements LE and a portion of the bottom surface and side surface of the contact electrode CTE. In one or more embodiments, the first organic layer 210 may be arranged on the side surfaces of the conductive layer E1 of each of the light emitting elements LE. In one or more embodiments, the first organic layer 210 may be arranged on the side surfaces of the first semiconductor layer SEM1, the side surfaces of the active layer MQW, and the side surfaces of the second semiconductor layer SEM2 of each of the light emitting elements LE. For example, the first organic layer 210 may be arranged on a portion of each of the side surfaces of the second semiconductor layer SEM2.

When the fluidity of the first organic layer 210 is relatively small and/or the

first organic layer 210 is solid, the depth at which the light emitting element LE is inserted or embedded in the first organic layer 210 may be very small, or the light emitting element LE may be placed on the first organic layer 210 without being inserted or embedded in the first organic layer 210.

When the first organic layer 210 is a photosensitive organic film such as a photoresist, after the first organic layer 210 is hardened (soft baked) at a first temperature, at least a portion of each of the plurality of light emitting elements LE may be inserted into the first organic layer 210. Then, the first organic layer 210 may be completely hardened at a second temperature higher than the first temperature. The first temperature may be approximately 100° C., and the second temperature may be approximately 230° C., but the embodiments of the present disclosure are not limited thereto. For example, the process of completely curing the first organic layer 210 at the second temperature may be performed for approximately 30 minutes.

In contrast, if the second protective layer INS2 is formed with ITO (Indium Tin Oxide) instead of IZO (Indium Zinc Oxide), wet etching may not be performed in the subsequent etching process because ITO crystallizes at around 200° C. Therefore, in one or more embodiments, because the second protective layer INS2 is formed with IZO having a crystallization temperature of about 600° C. or higher, etching of the second protective layer INS2 is possible during the subsequent wet etching.

Third, in act S130 of FIG. 14, a connection electrode is formed (S130 of FIG. 14). A connection electrode BE is formed to connect the second protective layer INS2 of the light emitting element LE arranged on the first organic layer 210 and the pixel electrode PXE.

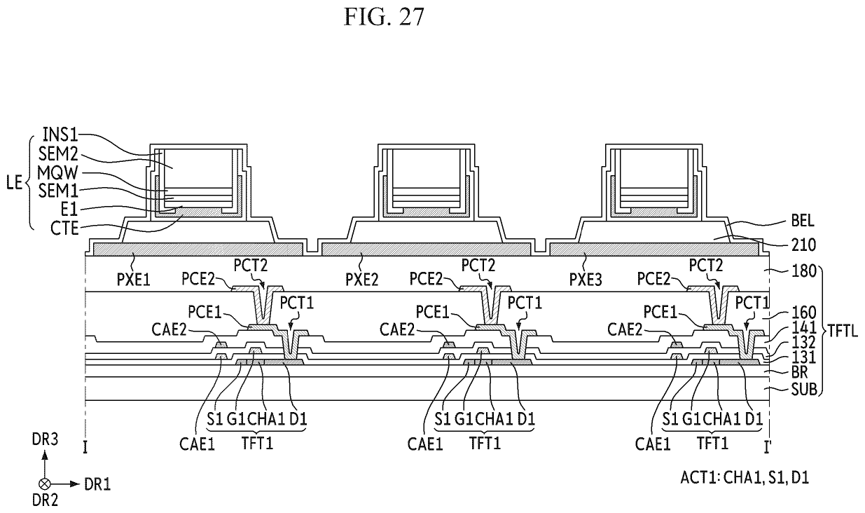

For example, as shown in FIG. 27, a connection electrode material layer BEL is formed on the entire surface of the circuit board SUB. For example, the connection electrode material layer BEL may be a material that may be etched by the same etchant as the second protective layer INS2. For example, if (e.g., when) formed as the second protective layer INS2, the connection electrode material layer BEL may include indium zinc oxide (IZO). In some embodiments, the connection electrode material layer BEL may include Indium Tin Oxide (ITO) (because there may be no heat treatment process of 200° C. or higher in the subsequent process).

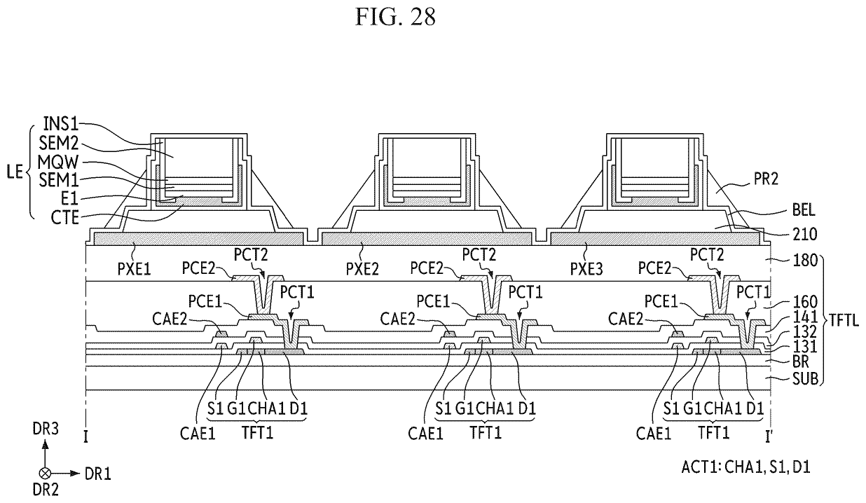

As shown in FIG. 28, a third mask pattern PR2 is formed using a photoresist, and the connection material layer BEL that is exposed and not covered by the third mask pattern PR2 is etched by the etchant to form a connection electrode BE. When the electrode material layer BEL is etched, a portion of the second protective layer INS2 is exposed, and the exposed second protective layer INS2 may be etched.

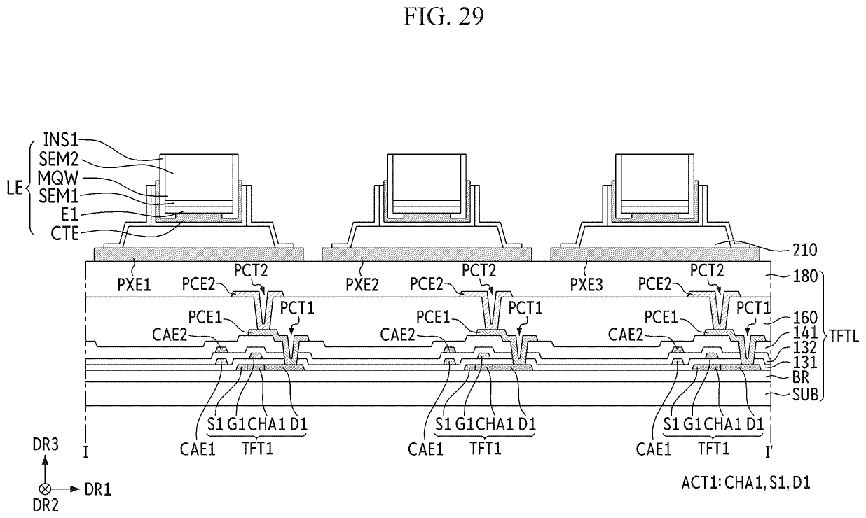

Thereafter, as shown in FIG. 29, the third mask pattern (PR2 of FIG. 28) may be removed by an ashing process.

In one or more embodiments, the height of the connection electrode BE and the second protective layer INS2 may vary depending on the formation height of the third mask pattern PR2.

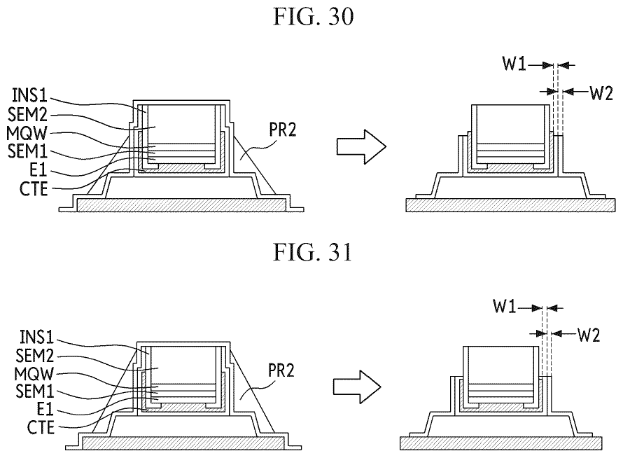

For example, referring to FIG. 30, when the third mask pattern PR2 is formed lower than the height of the contact electrode CTE, the height of the connection electrode BE and the second protective layer INS2 may be formed lower than the height of the second contact electrode CTE.

In contrast, when the third mask pattern PR2 is formed with a first height that is lower than the height of the contact electrode CTE, the height of the second protective layer INS2 and the connection electrode BE may vary depending on the thickness of the second protective layer INS2 and the connection electrode BE. This is because the difference in etching time occurs depending on the thickness of the second protective layer INS2 and the connection electrode BE. Therefore, the thicker the thickness, the more difficult it is to etch and the higher the height may be formed. For example, as shown in FIG. 10, when the thickness W1 of the second protective layer INS2 is thicker than the thickness W2 of the connection electrode BE, the height of the connection electrode BE may be formed lower. Furthermore, as shown in FIG. 11, when the thickness W1 of the second protective layer INS2 is thinner than the thickness W2 of the connection electrode BE, the height of the second protective layer INS2 may be formed lower.

In some embodiments, referring to FIG. 31, when the formation height of the third mask pattern PR2 is formed higher than the contact electrode CTE, the height of the second protective layer INS2 and the connection electrode BE may be formed higher than the height of the contact electrode CTE.

In one or more embodiments, the second protective layer INS2 may be formed to cover the upper portion of the contact electrode CTE.

However, because the second protective layer INS2 is a conductive protective layer, it may be positioned apart from the top surface of the light emitting element LE so as not to contact the common electrode CE formed subsequently. Therefore, the third mask pattern PR2 may be formed lower than the top surface of the light emitting element LE.

Fourth, in act S140 of FIG. 14, the common electrode CE is formed. (S140 of FIG. 14).

A second organic layer 211 and a third organic layer 212 are formed to fix (e.g., affix) the light emitting elements LE and to flatten (e.g., substantially flatten or substantially planarize) the steps (e.g., stepped portions) caused (or formed) by the light emitting elements LE. The third organic layer 212 is formed so as not to cover all the light emitting elements LE. For example, the third organic layer 212 may expose the top surface of the light emitting elements LE.

Then, a common electrode CE is formed on the third organic layer 212 and the light emitting elements LE. The common electrode CE may be electrically connected to the second semiconductor layer SEM2 of the light emitting elements LE.

Fifth, in act S150 of FIG. 14, a light blocking layer, a wavelength conversion layer, a light transmission layer, and a color filter layer are formed sequentially.

A first capping layer CAP1 is formed on the third organic layer 212 and the light emitting elements LE, and a first light blocking layer BM1 and a second light blocking layer BM2 are formed on the first capping layer CAP1 so as not to overlap with the light emitting elements LE in the third direction DR3. Then, a second capping layer CAP2 covering the first light blocking layer BM1, the second light blocking layer BM2, and the first capping layer CAP1 is formed. Then, a reflective film RF covering the second capping layer CAP2 arranged on the first light blocking layer BM1 and the second light blocking layer BM2 is formed.

Then, a first light conversion layer QDL1 is formed on each of the first sub-pixels SPX1, a second light conversion layer QDL2 is formed on each of the second sub-pixels SPX2, and a light transmission layer TPL is formed on each of the third sub-pixels SPX3. Then, a third capping layer CAP3 covering the first light conversion layer(s) QDL1, the second light conversion layer(s) QDL2, and the light transmission layer(s) TPL is formed. Then, a fourth organic layer 213 is formed on the third capping layer CAP3.

Then, a first color filter CF1 is formed on the fourth organic layer 213 overlapping the first light conversion layer(s) QDL1 in the third direction DR3, a second color filter CF2 is formed overlapping the second light conversion layer(s) QDL2 in the third direction DR3, and a third color filter CF3 is formed overlapping the light transmission layer(s) TPL in the third direction DR3. The first color filter CF1, the second color filter CF2, and the third color filter CF3 may all be formed in the area overlapping the first light blocking layer BM1 and the second light blocking layer BM2 in the third direction DR3.

Then, a fifth organic layer 214 is formed on the first color filter CF1, the second color filter CF2, and the third color filter CF3.

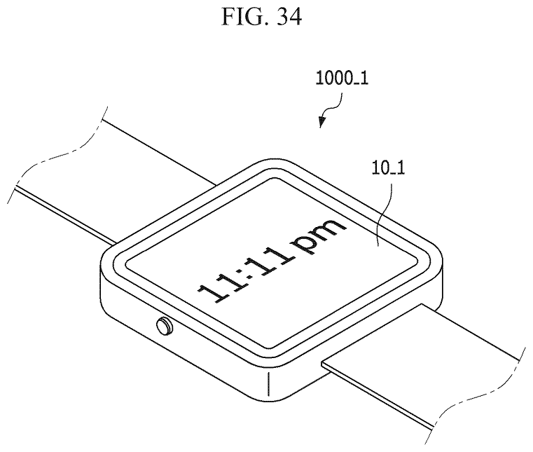

FIG. 34 is an example perspective view of a smart watch including a display device according to one or more embodiments.

Referring to FIG. 34, a display device 10_1 according to one or more embodiments may be applied to a smart watch 1000_1 which is one of smart devices.

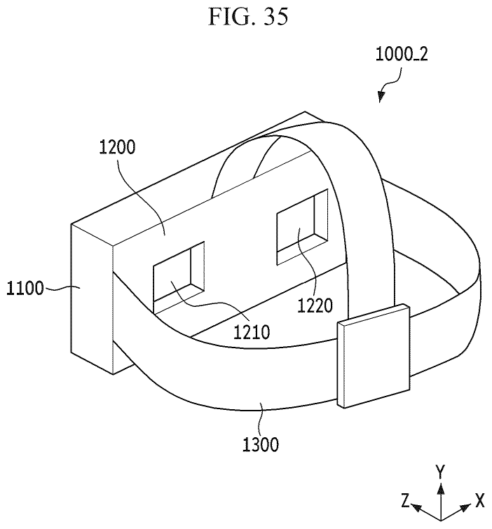

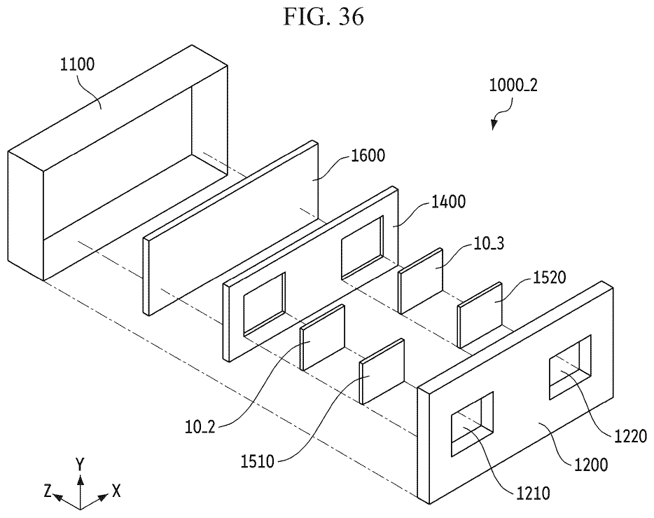

FIGS. 35 and 36 are example perspective views of a virtual reality (VR) device including a display device according to one or more embodiments.

Referring to FIGS. 35 and 36, a head mounted display device 1000_2 according to one or more embodiments includes a first display device 10_2, a second display device 10_3, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_2 provides an image to one of a user's eyes (e.g., left eye), and the second display device 10_3 provides an image to another of the user's eyes (e.g., a right eye). Hereinafter, by way of example, the device will be described as having the first display device 10_2 provide an image to the user's left eye, and the second display device 10_3 provide an image to the user's right eye. Each of the first display device 10_2 and the second display device 10_3 is substantially the same as the display device 10 described with reference to FIGS. 1 and 2. Therefore, a redundant description of the first display device 10_2 and the second display device 10_3 will not be provided.

The first optical member 1510 may be arranged between the first display device 10_2 and the first eyepiece 1210. The second optical member 1520 may be arranged between the second display device 10_3 and the second eyepiece 1220. Each of the first optical member 1510 and the second optical member 1520 may include at least one convex lens.

The middle frame 1400 may be arranged between the first display device 10_2 and the control circuit board 1600 and may be arranged between the second display device 10_3 and the control circuit board 1600. The middle frame 1400 supports and fixes the first display device 10_2, the second display device 10_3, and the control circuit board 1600.

The control circuit board 1600 may be arranged between the middle frame 1400 and the display device housing 1100. The control circuit board 1600 may be connected to the first display device 10_2 and the second display device 10_3 through a connector. The control circuit board 1600 may convert an image source received from the outside into digital video data DATA and transmit the digital video data DATA to the first display device 10_2 and/or the second display device 10_3 through the connector.

The control circuit board 1600 may be to transmit the digital video data DATA corresponding to a left image improved or optimized for a user's left eye to the first display device 10_2 and transmit the digital video data DATA corresponding to a right image improved or optimized for the user's right eye to the second display device 10_3. In one or more embodiments, the control circuit board 1600 may be to transmit the same digital video data DATA to the first display device 10_2 and the second display device 10_3.

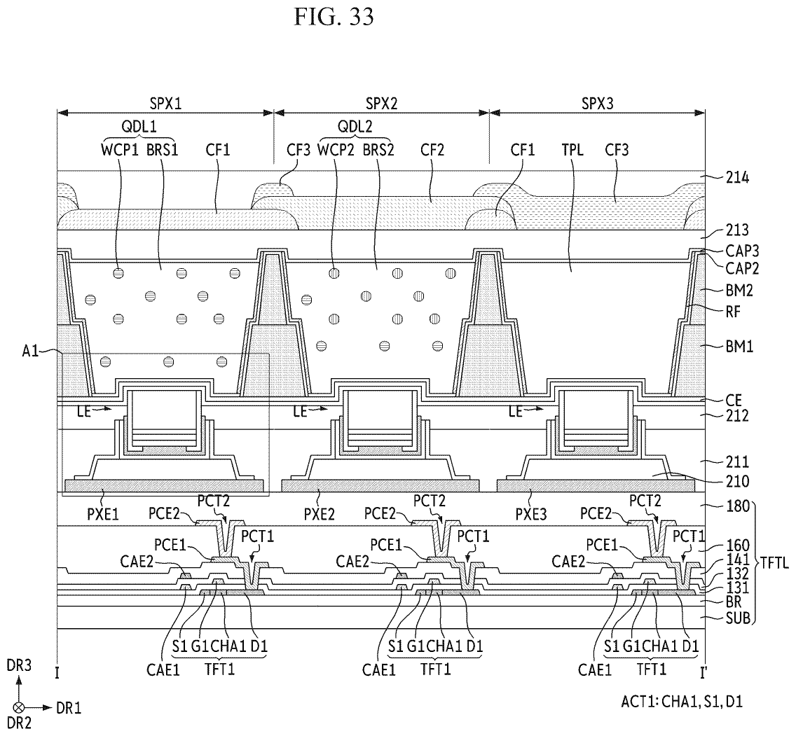

The display device housing 1100 houses the first display device 10_2, the second display device 10_3, the middle frame 1400, the first optical member 1510, the second optical member 1520, and the control circuit board 1600. The housing cover 1200 is placed to cover an open surface of the display device housing 1100. The housing cover 1200 may include the first eyepiece 1210 on which a user's left eye is placed and the second eyepiece 1220 on which the user's right eye is placed. Although the first eyepiece 1210 and the second eyepiece 1220 are arranged separately (e.g., spaced apart) in FIGS. 33 and 34, the present disclosure is not limited thereto. The first eyepiece 1210 and the second eyepiece 1220 may also be combined into one (e.g., may be integral).

The first eyepiece 1210 may be aligned with the first display device 10_2 and the first optical member 1510, and the second eyepiece 1220 may be aligned with the second display device 10_3 and the second optical member 1520. Therefore, a user can view an image of the first display device 10_2, which is enlarged as a virtual image by the first optical member 1510, through the first eyepiece 1210 and can view an image of the second display device 10_3, which is enlarged as a virtual image by the second optical member 1520, through the second eyepiece 1220.

The head mounted band 1300 fixes the display device housing 1100 to a user's head so that the first eyepiece 1210 and the second eyepiece 1220 of the housing cover 1200 are kept placed on the user's left and right eyes, respectively. When the display device housing 1200 is implemented to be suitably lightweight and small, the head mounted display device 1000_2 may include an eyeglass frame as illustrated in FIG. 35 instead of the head mounted band 1300.

In one or more embodiments, the head mounted display device 1000_2 may further include a battery for supplying power, an external memory slot for accommodating an external memory, and an external connection port and a wireless communication module for receiving an image source. The external connection port may be a universe serial bus (USB) terminal, a display port, and/or a high-definition multimedia interface (HDMI) terminal, and the wireless communication module may be a 5G communication module, a 4G communication module, a Wi-Fi module, and/or a Bluetooth module.

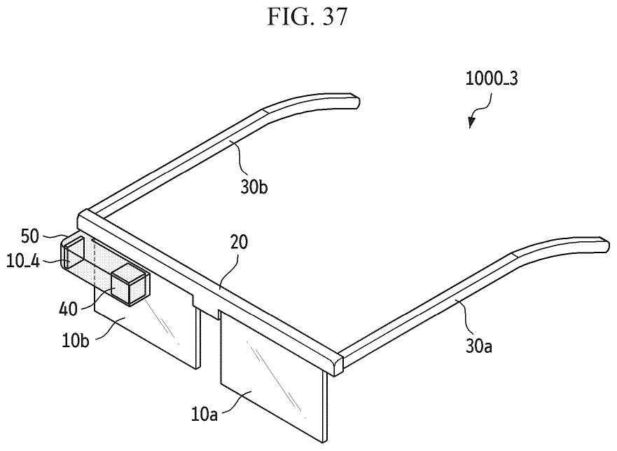

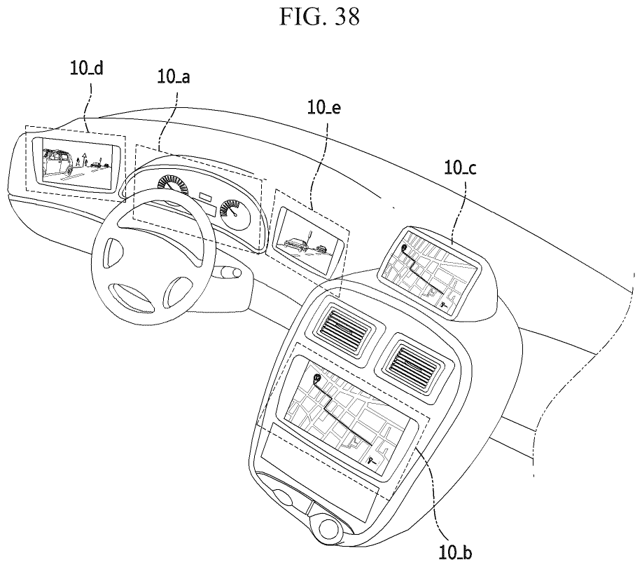

FIG. 37 is an example view of a VR device including a display device according to one or more embodiments. FIG. 37 illustrates a VR device 1000_3 to which a display device 10_4 according to one or more embodiments has been applied.

Referring to FIG. 37, the VR device 1000_3 according to one or more embodiments may be a device in the form of glasses. The VR device 1000_3 according to the embodiments may include the display device 10_4, a left lens 10a, a right lens 10b, a support frame 20, eyeglass frame legs 30a and 30b, a reflective member 40, and a display device housing 50.

In FIG. 37, a case where the VR device 1000_3 is a glasses-type or kind display device including the eyeglass frame legs 30a and 30b is illustrated as an example. For example, the VR device 1000_3 according to the embodiments is not limited to the one illustrated in FIG. 37 and can be applied in one or more suitable forms to one or more suitable other electronic devices.

The display device housing 50 may include the display device 10_4 and the reflective member 40. An image displayed on the display device 10_4 may be reflected by the reflective member 40 and provided to a user's right eye through the right lens 10b. Accordingly, the user may view a VR image displayed on the display device 10_4 through the right eye.

Although the display device housing 50 is arranged at a right end of the support frame 20 in FIG. 37, the present disclosure is not limited thereto. For example, the display device housing 50 may also be arranged at a left end of the support frame 20. In this case, an image displayed on the display device 10_4 may be reflected by the reflective member 40 and provided to the user's left eye through the left lens 10a. Accordingly, the user may view a VR image displayed on the display device 10_4 through the left eye. In one or more embodiments, the display device housing 50 may be arranged at both (e.g., simultaneously) the right end and the left end of the support frame 20. In this case, the user may view a VR image displayed on the display device 10_4 through both (e.g., simultaneously) the left eye and the right eye.

FIG. 38 is an example perspective view illustrating a vehicle instrument cluster and center fascia including display devices according to one or more embodiments. FIG. 38 illustrates a vehicle to which display devices 10_a through 10_e according to one or more embodiments have been applied.

Referring to FIG. 38, the display devices 10_a through 10_c according to the embodiment may be applied to an instrument cluster of the vehicle, a center fascia of the vehicle, and/or a center information display (CID) arranged on a dashboard of the vehicle. In one or more embodiments, the display devices 10_d and 10_e according to the embodiments may be applied to room mirror displays that replace side mirrors of the vehicle.

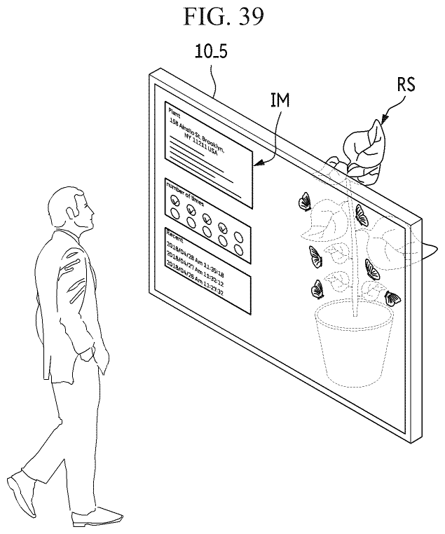

FIG. 39 is an example perspective view of a transparent display device including a display device according to one or more embodiments.

Referring to FIG. 39, a display device 10_5 according to one or more embodiments may be applied to a transparent display device. The transparent display device may be to transmit light while displaying an image IM. Therefore, a user located in front of the transparent display device cannot only view the image IM displayed on the display device 10_5 but also view an object RS and/or the background located behind the transparent display device. When the display device 10_5 is applied to the transparent display device, a substrate of the display device 10_5 may include a light transmitting portion that can transmit light or may be made of a material that can transmit light.

It should be understood, however, that the aspects and features of embodiments of the present disclosure are not restricted to the one set forth herein.

The above and other aspects of the present disclosure will become more apparent to one of ordinary skill in the art to which the present disclosure pertains by referencing the claims, with equivalents thereof to be included therein.

What is claimed is:

1. A display device comprising:
a substrate;
a pixel electrode on the substrate;
an organic layer on the pixel electrode;
a light emitting element on the organic layer, the light emitting element comprising a semiconductor stack, a first protective layer, a contact electrode, and a second protective layer; and
a connection electrode connecting the light emitting element and the pixel electrode,
wherein the first protective layer is an insulating protective layer, the second protective layer is a conductive protective layer, and
wherein the connection electrode and the second protective layer are etchable with the same etchant.

2. The display device of claim 1,
wherein the second protective layer comprises a conductive light-transmitting material.

3. The display device of claim 2,
wherein the contact electrode comprises aluminum,
wherein the second protective layer comprises Indium Zinc Oxide (IZO), and
wherein the connection electrode comprises at least one selected from among Indium Tin Oxide (ITO) and Indium Zinc Oxide (IZO).

4. The display device of claim 1,
wherein the contact electrode is on one side of the semiconductor stack and covers the one side while being spaced apart from a top surface of the semiconductor stack by a first distance.

5. The display device of claim 4,
wherein the second protective layer is on the one side of the semiconductor stack and covers the one side while being spaced apart from the top surface of the semiconductor stack by a second distance, the second distance being further than the first distance.

6. The display device of claim 5,
wherein the connection electrode is on the one side of the semiconductor stack, is further away from the semiconductor stack than the second protective layer, and is spaced apart from the top surface of the semiconductor stack by a third distance, the third distance being further than the first distance.

7. The display device of claim 6,
wherein the second distance and the third distance are the same, and thicknesses of the second protective layer and the connecting electrode are the same.

8. The display device of claim 6,
wherein the second distance is closer than the third distance and a thickness of the second protective layer is thicker than a thickness of the connection electrode.

9. The display device of claim 6,
wherein the third distance is closer than the second distance and a thickness of the connection electrode is thicker than the thickness of the second protective layer.

10. The display device of claim 4,
wherein the second protective layer is on the one side of the semiconductor stack to cover the one side, is further away from the semiconductor stack than the contact electrode, covers a top portion of the contact electrode, and is spaced apart from the top surface of the semiconductor stack by a second distance, the second distance being closer than the first distance.

11. The display device of claim 10,
wherein the connection electrode is on the one side of the semiconductor stack, is further away from the semiconductor stack than the second protective layer and is at a third distance from the top surface of the semiconductor stack, the third distance being equal to the second distance.

12. The display device of claim 1,
wherein the connection electrode is not in direct contact with the contact electrode and is electrically connected to the contact electrode through the second protective layer.

13. The display device of claim 1,
wherein the second protective layer is in direct contact with the organic layer.

14. The display device of claim 1,
wherein the semiconductor stack further comprises,
a first semiconductor layer on the organic layer and comprising a semiconductor material layer doped with a first conductive dopant;
an active layer on the first semiconductor layer; and
a second semiconductor layer on the active layer and comprising a semiconductor material layer doped with a second conductive dopant.

15. A method of manufacturing a display device, the method comprising:
forming a light emitting element comprising a semiconductor stack, a first protective layer, a contact electrode, and a second protective layer on a semiconductor substrate, wherein the first protective layer is an insulating protective layer, and the second protective layer is a conductive protective layer;
bonding the light emitting element on a circuit board comprising a pixel electrode;
depositing an electrode material layer on an entire surface of the circuit board, and then etching a portion of the electrode material layer and a portion of the second protective layer with the same etchant utilizing a mask pattern.

16. The method of claim 15, wherein
the bonding the light emitting element comprises:
forming an organic layer on the pixel electrode and performing a first cure, transferring the light emitting element onto the organic layer and performing a second cure, and
wherein the second protective layer has a crystallization temperature higher than a second curing temperature of the organic layer,
wherein the second curing temperature is a temperature of 200° C. or more and 250° C. or less,
wherein the second protective layer is Indium Zinc Oxide (IZO).

17. The method of claim 15, wherein
the bonding the light emitting element comprises:
transferring the light emitting element formed on the semiconductor substrate to a relay substrate, transferring the light emitting element on the relay substrate to a transfer substrate, and then transferring the light emitting element on the transfer substrate to the circuit board.

18. The method of claim 17, wherein the transfer substrate to which the light emitting element is transferred is cleaned with a chemical solution, and the chemical solution is configured to peel off the contact electrode and does not react with the second protective layer.

19. The method of claim 15, wherein the etching a portion of the electrode material layer and a portion of the second protective layer with the same etchant comprises:
forming a mask pattern so that a photoresist covers a side surface of the contact electrode, and etching the electrode material layer and the second protective layer on an upper portion of the light emitting element exposed by the mask pattern,
wherein the etched electrode material layer is to form a connection electrode, and
wherein a height of the second protective layer and a height of the connection electrode are determined according to a height of the photoresist.

20. An electronic device comprising:
a display device for displaying an image,
wherein the display device comprises,
a substrate;
a pixel electrode on the substrate;
an organic layer on the pixel electrode;
a light emitting element on the organic layer, the light emitting element comprising a semiconductor stack, a first protective layer, a contact electrode, and a second protective layer; and
a connection electrode connecting the light emitting element and the pixel electrode,
wherein the first protective layer is an insulating protective layer, the second protective layer is a conductive protective layer,
wherein the connection electrode and the second protective layer are etchable with the same etchant.
